(19) United States
(12) Patent Application Publication
(10) Pub. No.: US 2004/0245592 A1
(43) Pub. Date: Dec. 9, 2004

(54) Solid state microchannel plate photodetector

(75) Inventors: Eric S. Harmon, Norfolk, MA (US); David B. Salzman, Chevy Chase, MD (US)

Correspondence Address: Dave Garod Ph.D. Esq., PBWT, 1133 Ave of the Americas, New York, NY, 10036, US

(73) Assignee: Yale University, New Haven, CT

(21) Appl. No.: 10/837,175

(22) Filed: May 1, 2004

Related U.S. Application Data
(60) Provisional application No. 60/467,090, filed on May 1, 2003.

(51) Int. Cl. H01L 31/107

(52) U.S. Cl. 257/438

(57) ABSTRACT

A solid state microchannel plate is disclosed comprising a multiplicity of photodetector elements, each using limited gain from a small Geiger mode avalanche and summing the contributions thereof. An array of such multiplicities operates as a pixelated linear or area photodetector. In the preferred embodiment, a multiplicity of passively quenched photodetector elements connect to a common anode, and each photodetector element is passively quenched by its own current-limiting resistor in series with its cathode.

### CROSS-REFERENCE TO RELATED APPLICATION

This application claims priority from the U.S. Provisional Patent Application “Solid State Photon Detector,” filed May 1, 2003 as docket L3176-011, Ser. No. 60/467,090, incorporated herein by reference.

### FIELD OF THE INVENTION

This invention relates generally to the fields of solid state physics and electronics, more particularly to the design and fabrication of semiconductor photodetectors and photodetector arrays, and still more particularly to the design, fabrication and structure of elements of photodetectors, and arrays thereof, using avalanche gain.

### BACKGROUND OF THE INVENTION AND LIMITATIONS OF THE PRIOR ART

The single-shot detection of low optical fluxes with frequency response at high frequency, at or near room temperature, generally requires gain in the photodetector itself, not just in a preamplifier following the photodetector. Internal gain is needed because the best prior art preamplifiers produce electrical noise equivalent to about 100 input-referred electrons per pulse for pulse bandwidths exceeding approximately 100 MHz at room temperature, so a signal of roughly 100 photons divided by the photodetector's quantum efficiency would be below the noise floor. Repetitive sampling techniques, cryocooling, and slowing the bandwidth can sometimes be used to increase the signal-to-noise ratio (“SNR”), but are not general solutions. Producing many more than 1 electron per captured photon in the photodetector can offer a general solution to achieve improved SNR.

The principal prior art solution to the problem of high-speed detection of low optical fluxes include technologies based on high voltages in high vacuums (e.g. the photomultiplier tube (PMT), the microchannel plate (MCP), the intensified photodiode, and the electron-bombarded photodetector), all of which are fragile and expensive, and generally exhibit macroscopic dimensions incompatible with the microscale dimensions needed for many well-known and emerging applications. Alternative solutions such as superconducting tunnel junctions (See G. N. Gol'tsman, O. Okunev, G. Chulkova, A. Lipatov, A. Semenov, K. Smirnov, B. Voronov, A. Dzardanov, C. Williams, and R. Sobolewski, “Picosecond superconducting single-photon optical detector,” Applied Physics Letters, v. 79, p. 705, (2001).) or visible light photon counters) (VLPCs) (S. Takeuchi, J. Kim, Y. Yamamoto, and H. H. Hogue, “Development of a high-quantum efficiency single-photon counting system,” Applied Physics Letters, vol. 74, p. 1063, (1999).) only provide low-noise gain when operated at cryogenic temperatures, greatly limiting their applicability.

Distributed amplification using avalanche gain allows so-called charge-multiplying device (“CMD”) variants of a charge-coupled device (“CCD”) to achieve low noise amplification compatible with detection of single photons, but these devices are not generally operable at high bandwidths, and the charge-multiplying readout generally occupies a significant amount of chip area, necessitating a multiplexed readout rather than a dedicated amplifier for each pixel when used with a CCD detector array.

Gating or streaking techniques are often invoked to reject background noise and isolate a signal, or let any slow detector operate with a fast shutter, but are not general solutions for high duty cycle, sub-10 ns cycle times, but gating makes assumptions about knowing the timing of each event and having a low duty cycle, neither of which assumptions applies in the general case.

Semiconductor devices have historically been of lower quality, but workable. Conventional avalanche photodiodes (“APDs”) can offer linear amplification e.g. (10-100-fold) across useful dynamic ranges (e.g. 10,000:1) but are unable to detect single photons above their noise floor at or near room temperature when operating with detection bandwidths above something like 10 or 100 MHz bandwidth. Geiger mode avalanche gain, however, can provide sufficiently low-noise gain to detect single photons against the detector's background noise. APDs using Geiger mode are often called single-photon avalanche detectors, or “SPADs,” to distinguish them from conventional, linear APDs. However, SPADs do not distinguish a single-photon event from a multiple-photon event. A SPAD is a bistable device which detects a plurality of electrons (whether photogenerated or of thermal origin), and produces a binary output signal tantamount to “Yes, electrons were detected, or “No, zero electrons were detected”. A SPAD is capable of detecting single electrons, hence single photons if said photon generates an electron in the active region of the device.

SPADs operate in an unstable regime of bias above the breakdown voltage, so ought to produce a runaway current which would cause catastrophic failure due to excessive power dissipation. At first, until a Geiger event occurs, no free carriers are present to initiate breakdown, so no current flows. Absorption of a photon, ionizing radiation, or thermal generation will present a free carrier (i.e. electron or hole) to the APD's multiplication region, initiating the avalanche. Geiger mode avalanche requires positive feedback between electron multiplication and hole multiplication, so the current rises exponentially with time. But catastrophic destruction is averted by external circuitry, which generally limits the supply current to a magnitude less than the Geiger current, allowing the Geiger current to discharge the device capacitance, lowering the voltage until the device is no longer biased beyond breakdown, quenching the Geiger event. While it is possible for external circuitry to react to a Geiger event and assist in the quenching process by discharging the device capacitance faster, such active quenching is rarely faster than the self-quenching due to the Geiger discharge unless the bias supply current is too high (i.e. is not sufficiently limited) or the device capacitance is too large. After the device is quenched, a hold-off time is then necessary to allow any free or stored charge to be swept from the active region of the device, followed by a recharging cycle where the excess bias across the APD is restored. So-called active quenching circuits generally provide a significant speed-up of the recharge cycle rather than a significant reduction in the quench time.

In addition, due to the bistable nature of SPADs, a recovery time is needed after each Geiger event, during which the pixel must be cleared of charge carriers and reset to enable detection of another event. This results in a dead-time where the pixel is unable to detect any incident photons. At high count rates (typically 10-100 kcps for passively quenched and 1-10 Mcps for actively quenched APDs), a SPAD saturates, and is unable to detect incident photons, for a significant percentage of the time. The appreciable dead-time makes scaling a SPAD to large area problematic because the dark count rate associated with thermally generated carriers scales in proportion to the area, so larger devices are dominated by dark counts and their associated dead-time, reducing the portion of time during which the device is sensitive to light from true signals.

Recently, arrays of SPADs have been developed which partially solve the problems of discrete SPAD elements. (See Brian F. Aull, Andrew H. Loomis, Douglas J. Young, Richard M. Heinrichs, Bradley J. Felton, Peter J. Daniels, and Deborah J. Landers, “Geiger-Mode Avalanche Photodiodes for 3D Imaging,” Lincoln Laboratory Journal, v 13, p. 335 (2002). See http://www.ll.mit.edu/news/journal/pdf/13_{—}2aull.pdf, and P. Buzhan,B. Dolgoshein, L. Filatov, A. Ilyin, V. Kantserov, V. Kaplin, A. Karakash, F. Kayumov, S. Klemin, E. Popova, and S. Smirnov, Silicon photomultiplier and its possible applications,” Nuclear Instruments and Methods in Physics Research A. v. 504, p. 48, 2003.) They spread the input optical signal across an array of APD pixels, sharing the photons among a multiplicity of parallel avalanches. Such an array can be used to estimate the amplitude of an incident light pulse, since distributing the input photons across an array results in simultaneous detection events, with the number of triggered pixels proportional to the input photon flux.

Two general approaches to combining the output of an array of SPADs provide dynamic range. One employs an external readout integrated circuit (“ROIC”) to detect each individual Geiger event, using a dedicated circuit for each SPAD pixel. This approach is useful for imaging the spatial distribution of photons as well, but limits the density of pixels because of the pitch required to fit the detection and readout circuitry. The hybrid integration of the ROIC with the SPAD array necessitates some means for interconnecting a large number of connections (thousands to millions or more), introducing significant yield losses and additional failure mechanisms. Another approach employs monolithically integrated quenching circuitry for each pixel and array circuitry to combine the output of the array (or of a sub-array). A simple example of this monolithically integrated approach is to incorporate a simple resistive current limiter at the cathode (or anode) of each pixel, while combining the array outputs using a simple common anode (or common cathode) arrangement by simply connecting the anodes (or cathodes) of each pixel together. The common anode readout allows simple analog summation of the currents from each Geiger event. This approach has the advantages of not constraining the density of pixels, and of being readily implemented using monolithic integration of a common contacting layer for the SPAD arrays. Other monolithically integrated circuits are envisioned, including simple integrated amplifiers for each pixel (i.e. common collector amplifiers, with each pixel connected to the base of a heterojunction bipolar transistor, and using analog summation of the collector outputs to provide an additional transistor gain for each pixel), and simple threshold circuits (i.e. comparators) to output a precisely defined digital pulse for each detected Geiger event, which may also be summed through a common collector readout.

However, neither of these array solutions addresses other fundamental limitations of SPADs and SPAD arrays, including optical cross-talk, low geometrical fill factor, low photosensitive area, high after-pulsing rates, long dead-times, poor frequency response, poor time resolution, excessive power dissipation, and limited spectral sensitivity:

Optical cross talk scales as the product of optical generation inside a triggered pixel, the total geometric cross section for interaction between two pixels, and the single-photon sensitivity of other pixels. (See J. C. Jackson, D. Phelan, A. P. Morrison, R. M. Redfern, and A. Mathewson, “Characterization of Geiger Mode Avalanche Photodiodes for Fluorescence Decay Measurements,” Proceedings of SPIE Vol. 4650-07, January 2002.) Geiger mode avalanche gain process typically generates 10⁶-10¹⁰ electron-hole pairs in the active region of a device, some of which will radiatively recombine, emitting secondary photons. Though all reverse-based semiconductor junctions emit light proportional to current flow, the high gain and high electrical field in SPADs generate light efficiently and copiously). Some of these secondary photons may reach another pixel of the array. Since absorption of a single photon can trigger a pixel, the absorption of a secondary photon mimics a true event and triggers another pixel, causing a false detection event.

The geometrical fill factor for SPADs is the proportion of surface area capable of detecting single photons. Low geometrical fill factor follows from the need to isolate neighboring pixels geometrically in order to reduce optical cross talk, or the need to increase inter-pixel gutter margins or pitch to accommodate large per-pixel devices such as ROIC cells. An opaque barrier between pixels can be used to decrease optical cross talk while keeping a higher fill factor, but takes up area itself. Lens arrays can be used to increase the effective fill factor, but inevitably limit the numerical aperture of the pixels, which limit the utility and generality of an array.

The dark count rate of each SPAD pixel scales as its area, so in practice, the expected noise floor limits the maximum designable area. If the dark count rate of a pixel is too high, its photo-response becomes dominated by dead-time, making it inefficient as a photodetector. Increasing the effective active area of the photodetector instead by combining the outputs of an array of smaller pixels totaling the same area can avoid domination by dead-time at the same dark count rate. This effect occurs because the dead-time of individual pixels does not affect untriggered pixels.

After-pulsing occurs when charge carriers created by the avalanche process are trapped briefly in defects and subsequently re-emitted, initiating a new Geiger event. The likelihood scales as the trap density and the number of carriers. This trap-and-release mechanism is thermally activated, so is drastically worse at lower temperatures where storage times are longer.

The dead-time of a SPAD is the time period after a detection event where the device is no longer capable of detecting photons. While it is desirable to have as short a dead-time as possible to ensure availability of the detector element to detect subsequent photons, dead-time is bounded by the external circuitry reset speed, which in turn is limited by the gain-bandwidth of the circuitry, and after-pulsing, which is limited by trapping effects. External circuitry must be connected to the SPAD to allow the device to shut off after a detection event (otherwise it would be catastrophically destroyed as the avalanche gain process tends towards infinite gain and therefore infinite current), wait a predetermined time interval for substantially all of the free carriers to be swept out of the active region and e released from traps, and then reset the SPAD to a bias above breakdown to rearm the pixel for Geiger mode detection of the next event. Current implementations of SPADs exhibit dead-times in the range of 20 ns to tens of μsec.

The frequency response of a discrete SPAD pixel must be considered separately from the frequency response of a photodetector which aggregates the output of an array of SPAD pixels. The pixel frequency response is principally determined by three components: the rise-time of the Geiger detection event, the hold-off time, and the reset time necessary to recharges the pixel bias above breakdown, setting the device into the active Geiger mode. The rise-time of the Geiger detection event is generally dominated by the build-up time of the avalanche gain process. This build-up time depends on a number of parameters, including impact ionization coefficients (both electron and hole ionization coefficients), and the Geiger mode gain (defined as the number of electron-hole pairs generated during a Geiger event). The fact that Geiger mode operation requires feedback between electron and hole ionization generally makes the build-up time faster if electron and hole ionization coefficients are approximately equal. (See James S. Vickers, U.S. patent application Ser. No. 2003/0098463 A1, “Avalanche Photodiode for Photon Counting Applications and Method Thereof,” May 29, 2003.) The Geiger event causes an exponentially increasing current pulse to appear at the output until the gain mechanism is abruptly shut off as the device is quenched. After the device is quenched, it is identical to an APD operated in the linear mode, with the fall-time of the Geiger current dominated by the transit time of the carrier population through the device's depletion region. Next, the hold-off time is determined by a combination of the response speed of the circuitry, as well as the dead-time requirements necessary to ensure that after-pulsing is not significant. Finally, the rise-time of the reset event may also affect the pixel frequency response, particularly for approaches where the pixel is recharged through a high value resistor, resulting in a long RC time constant. The output pulse of a SPAD generally has a rise-time determined by the build-up time of the Geiger event, and a fall-time determined by the combination of the hold-off time and the reset time.

The aggregated array frequency response may differ from the pixel frequency response. It is determined primarily by the build-up time, which sets the frequency response of a SPAD array where the outputs of the array sum to form a single output waveform. While the hold-off and reset times together define a dead-time where an individual pixel is unable to detect a subsequent Geiger event, other pixels of the array remain available to detect additional events, so the primary metric for the frequency response of an array is the build-up time. In particular, if the array is connected in a common anode (or common cathode) arrangement, the Geiger event injects a current pulse into the common anode (or common cathode) with a rise-time dominated by the build-up time, and a fall-time dominated by the transit time through the depletion region of the device, after which the pixel is effectively disconnected from the common anode (or common cathode) readout and exhibits a high resistivity until the next detection event.

The time resolution of a SPAD indicates the ability of the device to determine a photon's absolute arrival time accurately. The fundamental limit to the time resolution of a SPAD is usually governed by jitter in the output pulse response compared to the incident photon arrival time. This jitter follows from two primary effects: the time a photoelectron takes to reach the avalanche gain region of the device, and the time a Geiger event takes to build-up. Time resolution is also a function of the external timing circuitry, which may contribute its own inherent jitter component.

The pulse-pair resolution describes the smallest time interval over which two successive photons can be distinguished. The pulse pair resolution is a relative measurement and may allow less uncertainty than the absolute time resolution.

Power dissipation also limits SPAD performance and reliability by raising the operating temperature and thereby increasing noise (dark counts) and failure rates. High internal gains, typically in the range of 10⁶-10¹⁰, generate and dissipate a significant amount of power when devices are operated at high count rates. Power dissipation can be particularly problematic for high density pixel arrays, where a pixel may by heated by power dissipated by nearby pixels or their ROIC circuitry. ROIC circuits usually dissipate far more power than pixels, so power density may limit pixel pitch by virtue of limiting ROIC pitch.

The spectral responsivity of a SPAD is determined by the probability of a photon converting into an electron-hole pair in the absorption region of the device. Most high performance SPADs have been produced using semiconducting silicon, limiting application to wavelengths where silicon has high absorption, mostly below 900 nm. Since dark noise (dark counts) scales as the volume of material, very thin active areas are commonly used. Consequently, silicon achieves high sensitivity only for wavelengths below about 900 nm.

SPADs have been demonstrated using other semiconductors too, but dominated by dark counts and after-pulsing. The prior art non-silicon SPADs generally operate with a large fraction of dead-time, very low duty cycle, and low availability.

### OBJECTS OF THE INVENTION

It turns out that nearly all of the above limitations of SPADs occur, directly or indirectly, as a result of excessively high internal gain. Most prior art designs have sought low noise and high internal gain to overcome higher noise from preamplifier read-out. But the 10⁶-10¹⁰:1 gain of a typical SPAD is significantly higher than optimal for low noise detection of single photons. Excellent modern electrical circuitry achieves a readout noise of about 100 electrons/pulse (for pulse speeds in excess of 100 MHz), so single photon detection can readily be achieved for low noise gain of more than 10² but far less than 10⁶.

By limiting the gain of a SPAD to far less than 10⁶, certain fundamental limitations of SPAD arrays and SPADs more generally can be mitigated:

Optical Cross Talk:

Since the optical generation rate of a SPAD is determined by the current flowing it, limiting the gain reduces the optical generation rate along with the current. Reducing the gain by an order of magnitude reduces the number of secondary photons and the optical cross talk in arrays by the same order of magnitude.

Geometrical Fill Factor:

Once gain is lowered, pixels can be placed closer together within a given optical cross talk budget, at least to the extent that optical cross talk is managed by pixel separation instead of more complex techniques like trench isolation and opaque barriers.

After-Pulsing:

The after-pulsing rate scales as density of traps and the number of carriers available to interact with the traps, hence as the gain, so reducing the number of free carriers reduces the capture probability and after-pulsing rate. (See W. J. Kindt and H. W. van Zeijl, “Modelling and Fabrication of Geiger mode Avalanche Photodiodes,” IEEE Transactions on Nuclear Science, v. 45, p. 715, June 1998.)

Frequency Response:

An avalanche entailing fewer carriers typically exhibits a faster rise-time and fall-time in a pixel, hence a higher frequency response. Lower gain allows a higher bandwidth at a given gain-bandwidth product.

Dead-Time:

A higher frequency response gives a shorter dead-time and higher per-pixel availability. In addition, the hold-off time can likewise be reduced because after-pulsing is reduced, enabling significant reductions in dead-time to be achieved.

Time Resolution:

A detection event with a sharper rising edge allows pulse detection circuitry to operate with less jitter.

Power Dissipation:

Power dissipation is set by the current-voltage product IV, so lowering the current by lowering the gain lowers the power. Lowering the power dissipation per detection event allows more detection events per second (higher pulse rates) and higher pixel densities to the extent they were limited by a temperature budget.

Spectral Sensitivity:

Spectral sensitivity depends on the semiconductor material used in the absorption region of the SPAD, so more freedom in the choice of semiconductor material supports more narrowness or breadth, as needed, in the spectral sensitivity. The dark count rate of SPADs realized in materials other than silicon is often dominated by after-pulsing, so reducing the after-pulsing rate, by reducing the Geiger mode gain, is key to making more semiconductors acceptable as absorption region candidates. Although the gain and absorption regions of a SPAD may be formed from the same or different semiconductor materials, the regions must be compatible enough for the defect density at their interface to be low enough to avoid swamping the device with dark counts caused by thermal generation in the absorption region and gain region, and after-pulsing from the gain region. (In an APD with separate absorption and multiplication (SAM) layers, the gain region only injects one type of carrier into the absorption region, and trapping of said carrier type will not create an after-pulse because the carrier type is repelled from the active gain region by the applied electrical field.)

In practice, all prior art structures and methods for limiting the Geiger mode gain have proven unsatisfactory. External circuitry is ordinarily required to detect a Geiger event, so a popular approach is to speed up the quenching process by actively reducing the voltage across an avalanching device, which also serves to reduce the dead-time and increase the duty cycle. (See S. Cova, M. Ghioni, A. Lacaita, C. Samori, and F. Zappa, “Avalanche photodiodes and quenching circuits for single-photon detection,” Applied Optics vol. 35, p. 1956, April 1996.) Active quenching circuitry requires a gain-bandwidth product on the order of 10⁶-10⁸ V/A times 10⁸ MHz in this example, since the Geiger event must be detected when the gain is low (e.g. 10³ carriers), and amplified to a macroscopic current pulse to generate a voltage pulse sufficient to cut the excess bias voltage across the APD to below breakdown. Such high gain entails a significant circuit delay due to fundamental gain-bandwidth limitations of circuitry, e.g. well below 100 MHz at high gain. Since the rise-time of a Geiger mode avalanche can be sub-ns to tens of ns, quenching a Geiger event with active circuitry is often incompatible with quenching to achieve low gain.

In contrast to active quenching, passive quenching is capable of achieving very fast quench times, and has already demonstrated 2.5 ns. (See A. Rochas, G. Ribordy, B. Furrer, P. A. Besse, and R. S. Popovic, “First Passively-Quenched Single Photon Counting Avalanche Photodiode Element Integrated in a Conventional CMOS Process with 32 ns Dead Time”, Proceedings of SPIE vol 4833, p. 107, 2002.) This is because the Geiger mode gain mechanism can be extremely fast, building up current within the device itself in tens or hundreds of ps. Provided that this internal current is not dissipated by external circuitry, the internal current is capable of discharging the device capacitance rapidly, limited only by the internal gain-bandwidth of the Geiger mode APD (typically in excess of 100 THz) and by the device capacitance. Indeed, the gain of a passively quenched Geiger mode APD is determined by the capacitance, and lowering the capacitance provides a means of lowering the gain.

Consequently, it is an object of the invention to use limited gain to achieve improved performance in pixelated arrays of SPADs. Limited gain is achieved by lowering the per-pixel capacitance such that the charge dissipated per detection event (related to the Geiger mode gain) is less than 10⁶. Limiting the Geiger mode gain advantageously lowers optical cross talk, after-pulsing, and power dissipation per detection event, which in turn allow higher pixel densities to be achieved by easing inter-pixel spacing constraints.

While some prior art attempts to reduce pixel noise by using very small photodetector active areas had the benefit of reducing capacitance, their performance improvement was countered by their low detectivity arising from the reduction in sensitive areas and fill factors.

The present invention achieve avoids these limitations by using further lowered gain to allow increased pixel densities, resulting in improved fill factors. Furthermore, it is an aspect of the invention to achieve lowered gain while maintaining large pixel active areas, which may be achieved through the use of SAM APD structures with thick, low noise depletion regions, coupled to thin absorption regions which avoid excessive thermal generation volume.

Another object of the invention is to achieve increased detectivity through the use of lowered gain. Increased detectivity is achieved through the use of higher pixel densities and higher fill factors, and through the higher detection efficiency available in lower gain devices. Higher detection efficiency is available because after-pulsing is lowered, allowing operation at higher excess bias, hence still higher detection efficiency. Similarly, spectral responsivity can be extended to longer wavelengths because lowered gain results in lowered after-pulsing, which often limits the performance of longer-wavelength single-photon detectors.

Another object of the invention is to achieve lowered pixel dead-times by lowering after-pulsing. Lowered dead-times correspond to higher pixel availability, hence higher array availability. Lowered dead-times also allow higher duty cycles to be achieved.

Another object of the invention is to achieve ungated operation. SPADs can often gate their photosensitivity to within a short time interval if a photon's arrival time is bounded, in order to reject the noise, dead-time and after-pulsing that dark counts engender. Decreasing a pixel's dead-time and after-pulsing increases its availability. Furthermore, the availability of a SPAD array is much higher than the availability of a single pixel large area photodetector of the same area, because in the SPAD array only a small fraction of the array elements will be unavailable at any given time, whereas for the single pixel large area photodetector the whole active area is unavailable during the pixel dead-time.

Another object of the invention is to achieve faster pixel rise-time and lower system jitter for circuitry that triggers on detection events. Faster pixel rise-time is achieved because limiting the gain generally allows higher bandwidth to be achieved due to gain-bandwidth constraints. Furthermore, since diffusion of the Geiger event across a SPAD pixel area is a function of the both the SPAD area and capacitance, limiting the gain results in both limited SPAD area and lowered SPAD capacitance, reducing the time needed for a Geiger event to diffuse into the entire active area of a pixel. Furthermore, another aspect of the invention is to achieve higher array bandwidth, particularly for arrays that aggregate the output through a common anode or similar connection. The bandwidth of such aggregate arrays is limited primarily by the pixel rise-time, so faster pixel rise-times leads to higher aggregate array bandwidth.

Consequently, some objects of the present invention, regarding a SPAD, are to: reduce Geiger mode gain; reduce the dead-time following a detection event; increase the duty cycle; reduce after-pulsing; reduce the rise-time, fall-time, or width of a the current pulse produced by capture of a photon; reduce the power dissipated per detection event; reduce, increase or extend the wavelength gamut of spectral sensitivity; detect single-photon events; reduce the dark count rate; and/or solve one or more problems limiting efficacy of prior art structures and methods.

Some other objects of the present invention, regarding an ensemble of SPADs forming an array used as a pixel, are to: reduce the overall dead-time, especially to effectively zero; increase the overall duty cycle; reduce optical cross talk; reduce absolute timing jitter; reduce the relative, pair-wise timing jitter; increase the pulse-pair resolution; reduce the pixel pitch; increase the geometrical fill factor; provide an output signal proportional to the number of photons in an input signal; discriminate dark counts from signal by thresholding the input at a minimum number of simultaneous photons greater than 1; simultaneously provide high detectivity, high Geiger mode performance, linear gray scale detection capability, and low-noise gain; optimize pixel and array structures and geometries to achieve limited Geiger mode gain with high photosensitivity on large areas; and/or solve one or more problems limiting efficacy of prior art structures and methods.

### BRIEF DESCRIPTION OF THE DRAWINGS

Various aspects, features, advantages and applications of the present invention are described in connection the Description of Illustrative Embodiments below, which description is intended to read in conjunction with the accompanying set of drawings, in which:

FIG. 1 depict the prior art approach to high-speed, ultra-sensitive optical detection using a microchannel plate (MCP) photomultiplier tube (PMT). FIG. 1A illustrates the layout of the MCP electron multiplier, and FIG. 1B provides a close-up cross-sectional view of two of the pores of the MCP.

FIG. 2 illustrates the passive quenching circuitry approach, with the circuit diagram in FIG. 2A and the equivalent circuit model in FIG. 2B. FIG. 2C shows the simulated current response of the simulated fast passive quenching approach, and FIG. 2D shows the simulated voltage response of the fast passive quenching approach.

FIG. 3 illustrate the thermal contribution to dark count rates as a function of the semiconductor absorption region. FIG. 3A show the thermal dark generation rate as a function of temperature for various semiconductor absorption regions. FIG. 3B shows the thermal dark generation rate as a function of effective cutoff wavelength of the absorption region, and FIG. 3C shows how an array of single photon detectors may be advantageously combined to reject uncorrelated dark counts while accurately detecting correlated signal photons.

FIG. 4 show the preferred embodiment. FIG. 4A shows the epitaxial layer structure of the preferred embodiment. FIG. 4B shows how two neighboring pixels of the preferred embodiment can be fabricated.

FIG. 5 show alternative pixel layouts for alternative implementations of the invention. FIG. 5A shows how a dielectric layer can be used to provide a field effect guard ring to ensure that perimeter effects and optical cross talk are negligible. FIG. 5B shows an alternative implementation of the field-effect guard ring structure.

FIG. 6 show alternative layer structure with a monolithic passive quench resistor integrated underneath the Geiger mode APD.

FIG. 7s shows an alternative embodiment using an active load to provide the quench resistor. FIG. 7A shows the layer stack of this alternative embodiment. FIG. 7B shows the circuit diagram of the monolithic active load quench resistor connected to the Geiger mode APD and transimpedance amplifier readout. FIG. 7C shows the common emitter characteristics of the active load transistor, showing the operating points of the transistor during a quenching cycle. FIG. 7D shows the geometrical layout of two pixels fabricated using the active load structure of FIG. 7A.

FIG. 8 shows an alternative pixel geometry using mesa isolation to provide further isolation between pixels.

FIG. 9 shows an alternative pixel geometry using diffused topside contacts to provide shaping of the electrical field.

FIG. 10 shows an alternative pixel geometry using a guard ring structure to provide shaping of the electrical field.

FIG. 11 show the geometrical pixel layouts on a square lattice FIG. 12 shows how a resistive common anode may be used to achieve an imaging array.

FIG. 13 show various hexagonal close packed pixel geometries. FIG. 13A shows a simple array of Geiger mode pixels on a hexagonal close packed lattice. FIG. 13B shows an array of Geiger mode pixels on a hexagonal close packed lattice with a guard ring structure for field shaping.

FIG. 14 show various pixel geometries. FIG. 14A shows etched mesas to provide a refractive lens to focus more of the incident light into the active absorption region of the invention. FIG. 14B shows etched mesas to provide a reflective lens to reflect and focus light incident through the substrate back into the active region of the device.

FIG. 15 shows an alternative embodiment where the field effect is used to achieve Geiger mode operation, and lateral transport of the Geiger charge is used to reset the device after quenching.

FIG. 16 shows how the invention may be used to produce a focal plane array, effective an imaging array of pixels, where each pixel is further subdivided into an array of Geiger mode APD elements in accordance with the invention.

### DETAILED DESCRIPTION OF THE ILLUSTRATIVE EMBODIMENTS

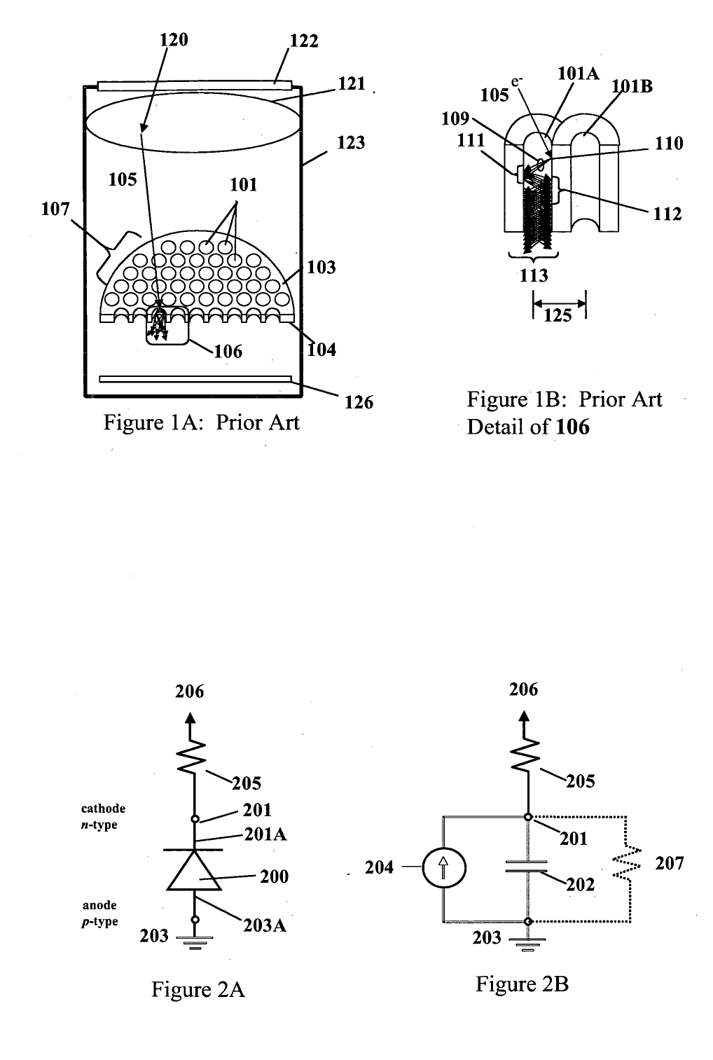

Reference is now made to FIG. 1A, showing a prior art approach to achieving high-speed, high sensitivity detection of optical photons using a microchannel plate electron multiplier. Since MCP operation requires a high vacuum, the interior of 123 must be evacuated. A window 122 allows incident photons 120 to enter into the vacuum environment of the MCP. When an incident photon 120 with sufficient photon energy strikes a photocathode 121, a photoelectron 105 is ejected into the vacuum. An electrical field is applied between the photocathode 121 and the top of the MCP electron multiplier 103 in order to accelerate photoelectron 105 towards the MCP 107. If photoelectron 105 gains sufficient energy from this electrical field, and if photoelectron 105 is incident on one of the pores 101 of the MCP 107, it may impact ionize at the sidewalls of the pores 101, resulting in a cascade of electrons in an efficient, low noise multiplication process. An electrical field is created within the pore by applying a high voltage (usually in the range of 500-1500 V) across the top side of the MCP 103 and the bottom side of the MCP 104.

Reference is now made to FIG. 1B, showing a magnified view of region 106 of FIG. 1A. The incident photoelectron 105 is accelerated towards the sidewall of the pore 101A, resulting in a impact ionization at point 110, typically causing 0-10 secondary electrons 109 to be ejected from the pore. An electrical field within the pore causes these secondary electrons to be accelerated until they again encounter the side wall of the pore at location 111, creating a second shower of secondary electrons, typically 0-10 secondary electrons per incident electron. This additional shower of secondary electrons is likewise accelerated down the pore until they again encounter the side wall of the pore at location 112, resulting in a third shower of secondary electrons. The process repeats itself until the electrons exit the MCP at the bottom 113 of the pore. These exiting electrons are accelerated into an anode 126, where they create a current that may be detected by external circuitry. The gain of each typical MCP pore is 1000-100,000, depending on the magnitude of the voltages applied between the photocathode 121 and the top of the MCP plate 103, between the top of the MCP plate 103 and the bottom of the MCP plate 104, and the bottom of the MCP plate 104 and the anode 126. Adjacent MCP pores such as 101A and 101B are separated by a distance 125, typically 5-100 μm. It is important to note that, when MCP electron multipliers are used to detect single photons, the gain of the pore is usually sufficient to result in a significant depletion of electrons from the side walls of the pore, generally resulting in a long dead-time as these electrons are replenished through a high resistance path that includes the top 103 and bottom 104 of the MCP, as well as the intrinsic resistance of the pore. This dead-time is typically longer than 1 μs.

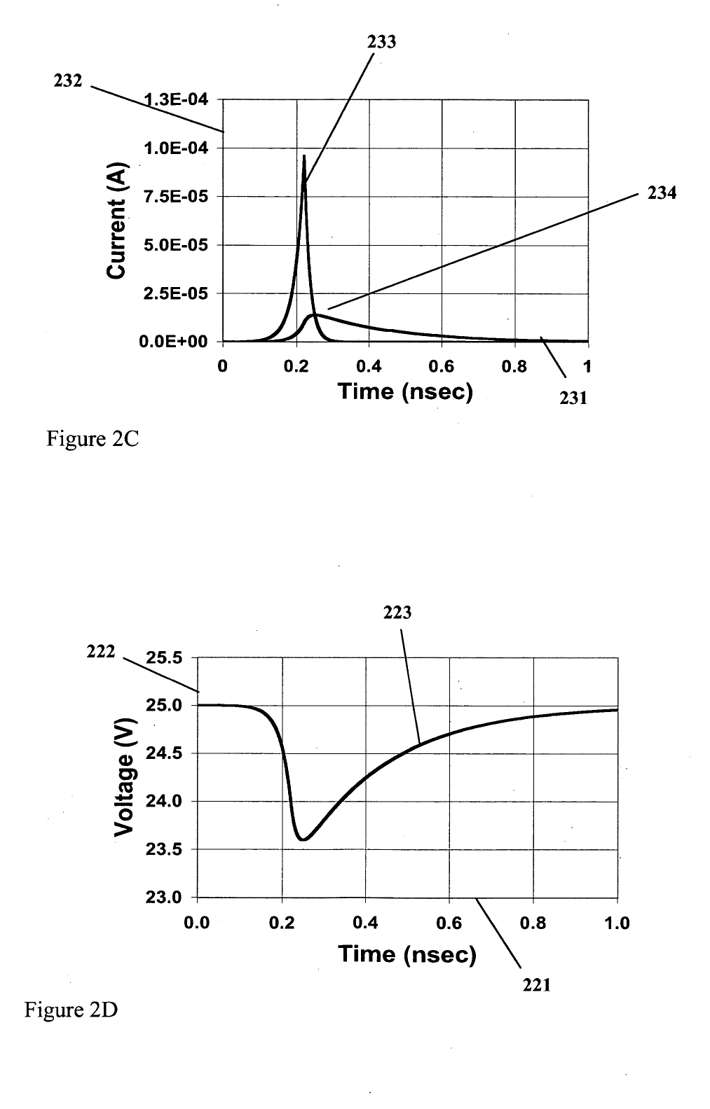

Reference is now made to FIG. 2 showing the passive quench circuitry used to achieve low gain. In the simple passive quench configuration a large value resistor 205 (typically between 100 kΩ and 1 MΩ) is connected in series with the SPAD 200. The bias voltage applied at 206 is chosen to be above the breakdown voltage of SPAD 200. If SPAD 200 is “Off” and has not detected a photon, then the current flowing through 200 is low. Ideally, this current is zero, but in practice a current component from the perimeter of the device may be flowing. In a properly designed device this perimeter current does not experience Geiger mode gain because the electrical field near the perimeter of the device is low. Therefore, this perimeter current is low compared with the current generated due to a Geiger event, and can generally be ignored. Also note that in a properly designed SPAD, current fluctuations in the active region of the device will eventually go to zero when all free carriers are swept out of the active region, allowing the device to be biased beyond breakdown and into the regime of Geiger avalanche gain. The SPAD 200 is connected to resistor 205 at point 201. In the FIG. 201A is the cathode of the SPAD, corresponding to the n-type side of the diode and 203A is the anode of the device, corresponding to the p-type side of the device. The anode 203A is connected to ground 203. The gain of SPAD 200 is dominated by three factors: the total capacitance of the device including parasitic capacitance, the amount of excess bias (bias beyond breakdown) applied across SPAD 200, and the current limiting response of the passive quench resistor. Any current that flows through the passive quench resistor during a quenching event acts to recharge the capacitance of SPAD 200, so SPAD 200 must exhibit a higher gain to discharge this additional current.

The primary factor determining the gain of a SPAD 200 is the total device capacitance (including all stray capacitance), which must be discharged by the Geiger current. In a properly designed passive quench circuit, the current through the passive quench resistor is a negligible correction to the gain. Larger recharge currents, achieved with a smaller passive quench resistor, disadvantageously increase the gain, but smaller recharge currents, achieved with a larger passive quench resistor, disadvantageously increase the reset time after the device has quenched through the RC time constant of resistor 205 and capacitor 202. Under the assumption of infinite passive quench resistor and instantaneous shutoff of current once the device has been quenched, the gain of a SPAD can be approximated by:

G=C×ΔV/q (1)

where ΔV is the bias above the breakdown voltage, or excess bias, on the SPAD pixel, and q is the charge of an electron. Equation 1 specifies the number of electrons needed to discharge the total capacitance C from a voltage of V_{BR}+ΔV to a voltage of V_{BR}, where V_{BR}is the breakdown voltage of the SPAD. In practice, the gain of the SPAD will be somewhat higher because the passive quench resistor 205 provides an additional charge component across capacitor C that must also be discharged to pull the SPAD bias voltage below V_{BR}, and the tail of the quench current persists for a short time after quenching, resulting in an additional discharging of the SPAD capacitor.

Gain can be controlled in several ways. It is a primary aspect of the invention to control the gain by achieving an appropriate value of the capacitance 202. Capacitance 202 can be lowered by minimizing parasitic capacitance, keeping the active area of the device small, and keeping the thickness of the depletion region thick. Reducing the device's active area lowers the capacitance, hence the gain, but also reduces detectivity due to the smaller active area. Increasing the thickness of the depletion region lowers the capacitance and may increase the detection efficiency (due to an increased absorption length), but generally increases the thermal dark count rate. Increasing the thickness of the depletion region using a separate absorption and multiplication (SAM) structure does not increase the absorption length (the absorption thickness does not change), but may result in only a small increase in thermal dark counts because thermal dark counts in a SAM structure are often dominated by the high generation rate in the absorption region.

We note that lower excess bias ΔV via equation 1 can also be used to lower the SPAD gain. But, lowering the excess bias generally degrades detection efficiency by reducing the photodetector sensitivity. Therefore lowering the excess bias ΔV is not advantageous unless lower excess bias ΔV can be achieved without degrading the photodetector sensitivity. In some embodiments of the invention, it is desirable to increase ΔV in order to achieve improved photodetector sensitivity. This can be achieved by combining increased ΔV with lowered SPAD capacitance in order to keep the gain low.

Fast passive quenching can self-quench and reset a SPAD pixel on a nanosecond time-scale. Fast self-quenching is achieved by making the capacitance C of the pixel small (less than 1 pF), such that the internal current generated through the avalanche process is sufficient to discharge the capacitor to a value below breakdown. Fast reset is achieved by making the RC time constant of the passive quench circuit very short, where R is set by resistor element 205 and C is set by the device capacitance 202. Throughout this specification, we use the term resistor broadly, intending to encompass all resistive means and current-limiting resistive means, including lumped and distributed effects proportional to the ratio of voltage to current. Capacitance includes all effects proportional to the ratio of charge to voltage, including parasitics and the real part of the complex admittance.

The equivalent circuit diagram for a passively quenched SPAD is shown in FIG. 2B. This illustration is schematic, and intended to convey the concept in simplest form. It is not intended to exclude circuits with an effect which one with ordinary skill in the art would recognize as commensurate. By monolithically integrating the passive quench resistor 205, the intrinsic device capacitance of the SPAD 200 can be made to dominate the total device capacitance 202. The equivalent circuit shown in FIG. 2B includes a shunt resistor 207, which can be used to model the perimeter leakage current through the SPAD 200. The parallel connected circuit elements 204, 202, and 207 form an equivalent circuit model of SPAD 200.

For the simplified numerical simulation of the SPAD 200 quenching response, shunt resistor 207 was neglected. The voltage change at node 201 due to the Geiger mode current is:

ΔV₁(t)=i₁(t)×R+(1/C)×∫i₂(t)δt (2)

where i₁(t) is the current through resistor 205, i₂(t) is the current through the capacitor 202, and ΔV₁(t) is the voltage drop across the capacitor at point 201. Note that ΔV₁(t) is also the voltage drop across resistor 205, allowing i₁(t) to be calculated (i₁(t)=ΔV₁(t)/R). For SPAD designs using small pixel capacitance 202 and large passive quench resistors 205, the Geiger mode gain of approximately C×ΔV₁/q.

Assuming a pixel has diameter of 5 μm, the capacitance 202 for a 1 μm semiconductor depletion layer thickness is roughly 2 fF (assuming low parasitic capacitance), so we calculate the gain to be approximately 1.1×10⁴×V_{excess}, where V_{excess} is the excess bias on the APD. A more accurate calculation indicates the gain is expected to be about 2×10⁴×V_{excess} due to charge replenishment through the passive quench resistor (assumed to be a 100 kΩ and the tail of the current response i₂(t). Fast self-quenching is therefore achieved, because the current response i₂(t) rapidly discharges the capacitor to ground. Self-quenching achieve one aspect of this invention, namely limiting the gain of the pixel to 2×10⁴ electrons to quench each volt of excess bias. Since the Geiger mode gain is defined as the number of electrons emitted per Geiger event, fast self-quenching provides a means of limiting to less than 10⁶, which is a significant reduction over prior art techniques which generally achieve gains exceeding 10⁶ per Geiger event due to device capacitances C in excess of 1 pF.

Simple numerical modeling results of the fast passive quench circuit using equation 2 are shown in FIGS. 2C and 2D. In FIG. 2C, the plot shows current 232 as a function of time 231. Curve 233 represents the Geiger current 204 as a function of time, and was calculated by assuming that the doubling time constant for the SPAD was 5 ps when the device was biased above breakdown, the transit time through the depletion region of the SPAD was 10 ps, and the doubling time constant for the SPAD biased below breakdown was 20 ps. A doubling time constant of 5 ps with a transit time of 10 ps is self-sustaining and will grow exponentially with time, so constitutes a reasonable model of the internal response of the device when biased above breakdown. A doubling time constant of 20 ps with a transit time of 10 ps is not self sustaining, and will eventually result in the current falling to zero, giving the current response 233. Note that a single photo-electron is injected into the active region at time zero, so the build-up time for the Geiger response is approximately 0.2 ns, in reasonable agreement with experimental results. Also shown in FIG. 2C is the recharge current 234 through resistor 205 as a function of time. The recharge current 234 rises as the voltage across the SPAD 200 drops, and continues after the Geiger response has completed, recharging the capacitor 202 and resetting SPAD 200 to an excess bias at node 201. In FIG. 2D, the simulated voltage response 222 at node 201 is plotted as a function of time 221. In this example, SPAD 200 is biased to 25 V at time zero, which simulates 1 V of excess bias. The Geiger event lowers the voltage on SPAD 200, overshooting the breakdown voltage of 24 V, due to the tail of the current response 233. The voltage response 223 recovers back to 25 V due to the recharge current 234. The result is detection of a Geiger event with nearly complete recovery in less than 1 ns. Furthermore, the current response 233 is very fast, and it is this current response that would dominate the frequency response of a SPAD array using a common anode connection in accordance with the invention.

The Geiger avalanche multiplication process has an inherent exponential rise-time during the initial build-up of the Geiger event. For very small devices, the diffusion time constant for spreading the Geiger avalanche throughout the entire high field region of the device is negligible, though this is not true of large area devices where it may take more than 100 ps for an initial filamentary breakdown to spread across the entire area of the device. For SPADs operated under high gain conditions, this exponential rise will saturate as a result of space charge lowering the avalanche gain and parasitic resistance restricting current flow.

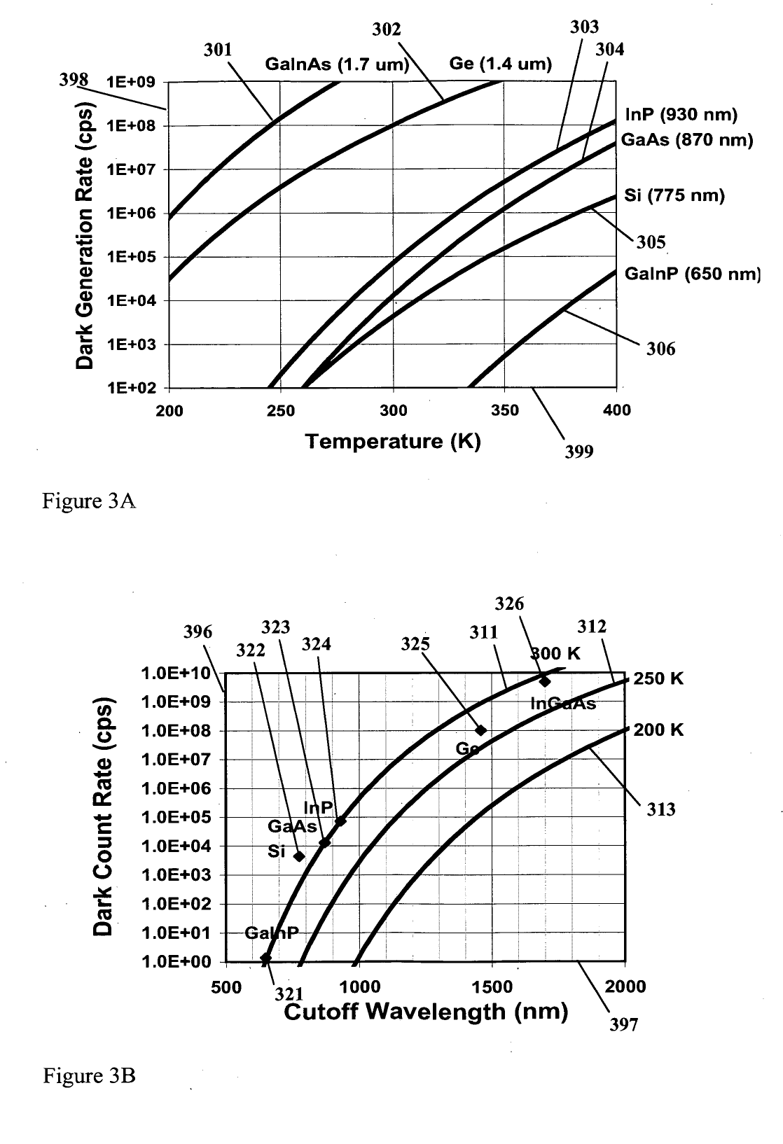

Reference is now made to FIG. 3, which illustrate the dependence of thermally generated dark counts on the choice of semiconductor materials in the active region of the SPAD.

Reducing the volume of the semiconductor active region of SPADs significantly reduces the dark count rate, and has made it possible for silicon SPADs to be operated at room temperature. (See Vasile, S., Gothoskar, P., Farrell, R., and Sdrulla, D., “Photon detection with high gain avalanche photodiode arrays,” IEEE Trans. Nuclear Science, v. 45, p. 720 (1998). M. Ghioni, S. Cova, I. Rech, and F. Zappa, “Monolithic Dual-Detector for Photon-Correlation Spectroscopy with wide Dynamic Range and 70-ps Resolution,” IEEE J. Quantum Electronics, v. 37, p. 1588 (2001). Also see A. Rochas, A. R. Pauchard, P-A. Besse, D. Pantic, Z. Prijic, and R. S. Popovic, “Low-Noise Silicon Avalanche Photodiodes Fabricated in Conventional CMOS Technologies,” IEEE Trans. Elect. Dev., v. 49, p. 387 (2002). Also see W. J. Kindt and H. W. van Zeijl, “Modeling and Fabrication of Geiger mode Avalanche Photodiodes,” IEEE Trans. Nuclear Science,. v. 45, p. 715 (1998).) Cooling an APD also decreases the dark count rate, but only somewhat.(See S. M. Sze, Physics of Semiconductor Devices 2^{nd} edition, p. 90, John Wiley & Sons, New York (1981). Also see K. A. McIntosh, J. P. Donnely, D. C. Oakley, A. Napoleone, S. D. Calawa, L. J. Mahoney, K. M. Molvar, E. K. Duerr, S. H. Groves, and D. C. Shaver, “InGaAsP/InP avalanche photodiodes for photon counting at 1.06 μm,” Appl. Phys. Lett., v. 81, p. 2505 (2002).)

The generation rate of free carriers inside a semiconductor depletion region is given by:

G=nᵢ/τ_{SRH} (3)

where ni is the intrinsic carrier concentration, G is the generation rate, and τ_{SRH} is the Schockley-Read-Hall recombination lifetime. Note that is some devices, the absorption region may not be depleted (See N. Li, R. Sidhu, Z. Li, F. Fa, X. Zheng, S. Wang, G. Karve, S. Demiguel, A. L. Holmes, Jr. and J. Campbell, “InGaAs/InAlAs avalanche photodiode with undepleted absorber,” Applied Physics Letters, v. 82, p. 2175 March 2003), an so the thermal generation rate equation 2 must be modified to account for minority carrier generation in doped regions. It is generally acceptable to treat τ_{SRH} as a slowly varying function of temperature, though ni has exponential dependence on temperature:

[symbol]

(4)

where N_{C}_{⁻} and N_{V} are the conduction and valence band density of states, respectively, E_{G} is the band gap, k_{B} is Boltzmann's constant, and T is the absolute temperature. For silicon at room temperature, decreasing the temperature by 8.8° C. halves nᵢ, and halves the thermal generation rate, G. This is why silicon SPADs are often cooled with solid state thermoelectric coolers (TECs). By comparison, a hypothetical semiconductor with the same density of states and τ_{SRH} as silicon could achieve that same factor of two decrease in nᵢ if its band gap were merely 0.036 eV higher, without cooling. A slightly larger band gap material enables a spectacularly lower dark count SPAD.

Excessive cooling, however, leads to runaway after-pulsing, counter-intuitively making the photodetector more noisy. Defect-assisted tunneling becomes problematic at lower temperatures as well.

Table I shows the band gap and intrinsic carrier concentration for selected semiconductors. By inspection, we see that the wide band gap of Ga_{0.5}In_{0.5}P is expected to achieve significantly lower thermal generation rate than silicon due to the decrease in ni by a factor of 10⁸-10¹⁰, even in the presence of a large difference in τ_{SRH} in these materials. Furthermore, wide band gap semiconductors exhibit a stronger temperature dependence via equation 4, indicating that even modest cooling of these semiconductors greatly reduces their generation rate.

In Table I, we calculated the noise equivalent power (“NEP”) expected for the devices built using the invention assuming that thermal generation dominates the dark count rate of the devices and the thermal generation rates shown in Table I. The NEP can be calculated from:

NEP=hν×√2×√J_{D}/(DE×FF) (5)

where J_{D} is the dark count rate, hν is the photon energy, DE is the single pixel detection efficiency for photons at the optical frequency ν and FF is the fill factor of the array, which is equivalent to the fractional area of the photodetector array that is sensitive to incident photons.

Reference is now made to FIG. 3A, which shows the estimated thermal dark generation rate 398 as a function of temperature 399 for the selected semiconductors shown in Table I. These curves were generated using equation 3 and the parameters shown in Table I, along with known semiconductor materials parameters. Curve 301 shows the thermal dark generation rate for InGaAs, Curve 302 shows the thermal dark generation rate for Ge, Curve 303 shows the thermal dark generation rate for InP, Curve 304 shows the thermal dark generation rate for GaAs, Curve 305 shows the thermal dark generation rate for Si, and Curve 306 shows the thermal dark generation rate for InGaP (band gap of InGaAs and InGaP shown in Table I). While Si generally has the lowest τ_{SRH} due to the maturity and purity of its materials technology, it also has a very large nᵢ because of its relatively small band gap and high density of states in the conduction band. The conduction band density of states is large because silicon is an indirect band gap material, and therefore exhibits a 6-fold degeneracy in its conduction band minimum, as well as a relatively shallow E-k dispersion relationship (i.e. a high density of states effective mass). State-of-the-art materials processing techniques for the lattice-matched compound semiconductors may result in generation lifetimes inferior to those for silicon by 5 orders of magnitude, which is still good enough to make the phenomenally smaller (8-10 orders of magnitude lower) nᵢ still out-compete higher τ_{SRH}.

Reference is now band to FIG. 3B, which shows the estimated thermal dark count rate 396 as a function of cutoff wavelength 397. Curves 311, 312 and 313 are “universal” curves independent of the material, showing the estimated dark count rates at 300 K, 250 K, and 200 K respectively. These “universal” curves were obtained by using InP as the prototype material, and scaling the intrinsic carrier concentration nᵢ as a function of band gap via equation 4. That is, all parameters for equation 4 correspond the InP, except for varying the band gap. The cutoff wavelength was assumed to be equal to the band gap. Also plotted in FIG. 3B are the 300 K results for the selected semiconductors from Table I using the values in equation 2. The cutoff wavelength chosen for these semiconductors correspond to the cutoff wavelength listed in Table I, which corresponds to the wavelength where the absorption falls below 10% in these devices. Point 321 corresponds to the calculated thermal dark generation rate for GaInP at 300 K, point 322 corresponds to the calculated thermal dark generation rate for silicon at 300 K, point 323 corresponds to the calculated thermal dark generation rate for GaAs at 300 K, point 324 corresponds to the calculated thermal dark generation rate for InP at 300 K, point 325 corresponds to the calculated thermal dark generation rate for Ge at 300 K, point 326 corresponds to the calculated thermal dark generation rate for InGaAs at 300 K.

FIG. 3B illustrates the clear advantage of using wider band gap materials to reduce the thermally generated dark count rates. FIG. 3B also illustrates that, even though silicon has exceptionally high materials quality, compound semiconductors can often outperform silicon, and provides a guide for the selection of the semiconductor for the active region of the device. FIG. 3B also illustrates the utility of building a SAM APD structure, using a wider band gap gain region coupled to a smaller band gap absorption region. The smaller band gap absorption region is used to provide high efficiency absorption of the photons of interest, and the thickness of the absorption region can be chosen to balance the trade off between absorption efficiency and dark count rate through equation 2. If the absorption region is coupled to a gain region with a wide enough band gap, the thermal dark count contribution of the gain region will be negligible, allowing significant freedom in the thickness of the gain region. Since one aspect of the invention is to control the gain by lowering the capacitance, it is a simple matter to lower the capacitance by making the gain region thicker, with no significant increase in the dark count rate. Indeed, a wider gain region also has the advantage of reduced tunneling (including defect-assisted tunneling), because a thicker gain region can generally operate at a slightly lower electrical field and still achieve the same detection efficiency. This is because the interaction length of carriers in the gain region is longer, allowing for more impact ionization events, and hence the ration of doubling time to transit time is improved. It is advantageous to minimize tunneling because even a single electron tunneling through the depletion region is capable of initiating a dark count as a source of noise. The only draw back to a wider gain region in a SAM structure is the necessity to increase the applied voltage to achieve breakdown conditions.

TABLE I

| | GaInP | GaAs | InP | Si | InGaAs | Ge |
|---|---|---|---|---|---|---|
| Band gap Eg [eV] | 1.9 | 1.42 | 1.35 | 1.12 | 0.74 | 0.66 |
| Cutoff wavelength* | 650 nm | 870 nm | 930 nm | 775 nm | 1.7 μm | 1.46 μm |
| (absorption length = 10 μm) | | | | | | |
| Intrinsic carrier concentration | 2.8E2 | 2.7E6 | 1.4E7 | 8.7E9 | 9.6E11 | 2.0E13 |
| nᵢ [cm−3] | | | | | | |
| Change in temperature for | −4.4 | −6.4 | −6.9 | −8.2 | −11.3 | −12.1 |
| halving of [° C.] | | | | | | |
| Change in nᵢ for a −30° C. | 97-fold | 33-fold | 26-fold | 15-fold | 7.1-fold | 6.2-fold |
| change in temperature | | | | | | |
| Schockley-Read-Hall | 1 μs | 1 μs | 1 μs | 10 ms | 1 μs | 10 ms |
| lifetime, τ_{SRH} | | | | | | |
| Dark generation rate for a | 0.005 Hz | 50 Hz | 280 Hz | 17 Hz | 19 MHz | 390 kHz |
| typical 5 μm diameter | | | | | | |
| device | | | | | | |
| Integrated dark generation | 1.4 Hz | 13 kHz | 72 kHz | 4.4 kHz | 4.8 GHz | 100 MHz |
| rate for a 16 × 16 pixel array | | | | | | |
| (˜50% fill factor if the | | | | | | |
| 16 × 16 array fills a | | | | | | |
| 100 μm × 100 μm | | | | | | |
| photodetector area) | | | | | | |
| NEP of 16 × 16 pixel array | 2.1E−18 | 1.5E−16 | 3.3E−11 | 1.4E−16 | 4.9E−14 | 1.0E−14 |
| (assumes 50% fill factor and | @ 640 nm | @ 850 nm | @ 920 nm | @ 540 nm | @ 1.6 μm | @ 1.1 μm |
| 50% detection efficiency)** | | | | | | |
| CAPTION: | | | | | | |
| Calculated materials properties of various semiconductors. The active region thickness was assumed to be 1 μm for all semiconductors. | | | | | | |
| NOTES: | | | | | | |
| *Cutoff wavelength estimated by determining wavelength where the absorption length is 10 μm, resulting in a less than 10% probability of | | | | | | |
| # absorption for the incident photon. (Absorption coefficients from S. Adachi, Optical Constants of Crystalline and Amorphous Semiconductors,” | | | | | | |
| # Kluwer Academic Publishers, Boston, 1999, and S. R. Kurtz et al., “Passivation of Interfaces in High Efficiency Photovoltaic Devices,” Materials Research Society Spring Meeting, May 1999). | | | | | | |

**Wavelength for NEP estimation is chosen such that the absorption coefficient is at least 10⁵/cm, enabling a probability of incident photon absorption of at least 63%.

Reference is now made to FIG. 3C, showing the advantage of SPAD arrays over single pixel SPADs when the incident signal consists of more than one photon per pulse. The false positives rate 394 is plotted as a function of temperature 395. Curve 353 shows the calculated false positives rate when the threshold of a discriminator is set at a level to detect single Geiger events for a SPAD array example using an InGaAs absorption region for detection of 1.5 μm photons. Curve 353 is therefore just the calculated total dark count rate of the SPAD array. Curve 354 shows the calculated false positives rate when the threshold of a discriminator is set at a level to detect two simultaneous Geiger events but reject single Geiger events for the same SPAD array. By restricting our positive identification to correlated pairs of Geiger events, a significant amount of un-correlated noise photons (due to thermally generated dark counts) can be rejected, resulting in significantly improved SNR. Similarly, Curve 355 shows the calculated false positives rate when the threshold of a discriminator is set at a level to detect 4 simultaneous Geiger events but reject any events with fewer simultaneous detection events. This curve shows a further reduction in the effective noise rate as uncorrelated dark events are more strongly suppressed. Also shown in FIG. 3B are is curve 352 showing the single event thermal dark count rates for a similar SPAD array using InP in the active region of the device, as well as curve 351 showing the single event thermal dark count rates for a similar SPAD array using silicon in the active region of the device. FIG. 3C illustrates the utility of SPAD arrays for detecting correlated photon pulses, particularly for devices where background count rates are high. Note that even very low dark count rate SPAD arrays may have a high background count rate if operated under high ambient optical fluxes, so noise thresholding will be useful for these devices as well.

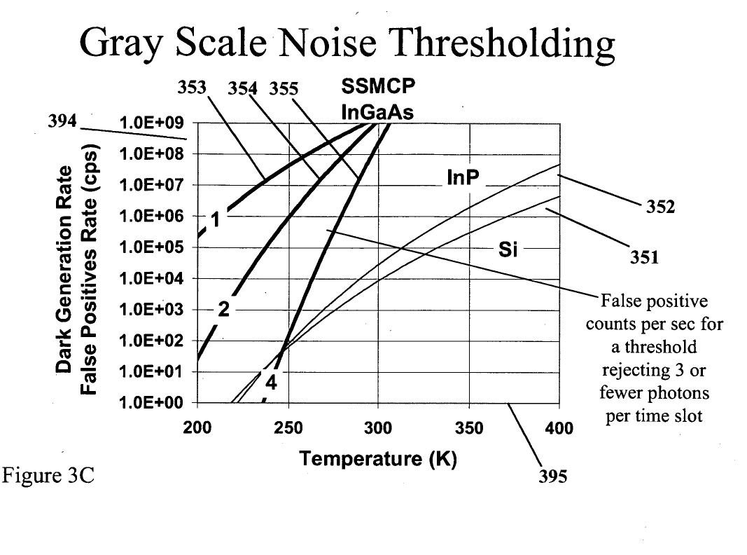

Reference is now made to FIG. 4, showing the preferred embodiment of the invention. FIG. 4A shows the layer stack of the preferred embodiment. The preferred embodiment is grown on a substrate 400 using conventional molecular beam epitaxy (MBE) or metal organic chemical vapor deposition (MOCVD). Substrate layer 400 may include an appropriate buffer layer also grown by MBE or MOCVD to provide improved semiconductor quality, if necessary. On top of substrate layer 400 is grown contact layer 401 to a thickness 421. In the preferred embodiment, this contact layer is used to form a low resistance contact to the common anode (or common cathode, depending on the doping). On top of contact layer 401 is grown absorption region 403 to thickness 423. The thickness and composition of region 403 is chosen to provide an optimal trade between absorption efficiency and dark count rate. On top of absorption region 403 is grown a charge control layer 405 with a thickness 425. The layer 405 serves to reduce the electrical field in layer 403, advantageously allowing the magnitude of the electrical fields in layers 403 and 407 to be different. Layer 407 is the gain region, and in general is produced in a material with a different properties from the absorption region. Generally, layer 407 has a larger band gap than layer 403, hence a large breakdown field. Charge control layer 405 therefore provides a means for allowing the electrical field in layer 407 to be large enough to initiate breakdown (and therefore initiate Geiger events), while keeping the field in layer 403 sufficiently low to avoid breakdown in layer 403. Breakdown in layer 403 is also generally avoided because the breakdown characteristics of layer 407 advantageously exhibit breakdown properties at least as good (e.g. less tunneling) as those in layer 403. The combination of layers 407, 405, and 403 is often referred to as a SAM APD (or SACM APD) structure, by allowing separation of the absorption (and collection) and multiplication functions of the device. Layer 407 is grown to a thickness 427. On top of layer 407 is grown a contact layer 409 to a thickness 429. Contact layer 407 allows ohmic contact to the cathode (or anode, depending on doping type) side of the device. On top of layer 409 is deposited transparent resistive layer 411 with a thickness of 431. Layer 411 may consist of an epitaxially grown layer provide sufficiently high resistance can be achieved using semiconductor materials, or layer 411 may consist of a post growth deposited layer, such as amorphous silicon carbide. The materials and thickness 431 of layer 411 are chosen such that layer 411 can be fabricated into the passive quench resistor. Obviously, the layers 403, 405 and 407 can equivalently be grown upside down, in the opposite time sequence, or both.

Reference is now made to FIG. 4B, showing how the layer structure of FIG. 4A can be fabricated into a SPAD array device. Only two pixels of the array are shown in the figure, which by extension, can be extended in 2 dimensions to form an array of any size and shape, notably including line arrays and area arrays such as rectangles. A common anode (or common cathode, depending on the doping type) contact 413 is applied to the substrate 400, making a low resistance ohmic contact through the substrate. By “common,” we mean able to be contacted by a multiplicity of the photodetector elements to be defined by patterning during wafer processing. Small mesa contacts 409A and 409B are defined in layer 409, with lateral dimension 417 and spacing 416. The electrical field lines between the contacts extending through the resistor layer 411, contact layer 409, gain layer 407, and being terminated in the charge control layer 405 are shown schematically by 414. While the majority of the electrical field will be terminated by the charge control layer 405, a small portion of the electrical field will penetrate into the absorption layer 403 in order to provide a force to accelerate absorbed photons into the gain layer 407. The spacing between the top contacts 412A and 412B is 414. The size of the top contacts 417 is generally as small as possible in order to keep the effective pixel small, reduce shadowing of the active area, and achieve the desired electrical field profile. Field crowding results in the high electrical field being generated in regions 415, which defines the active gain region of the device. Note that region 415 will only be a region of the gain layer 407, and will not fill the entire layer. This is advantageous, because it reduces perimeter effects, particularly performance-degrading perimeter breakdown. Furthermore, by keeping the high field region 415 small, after-pulsing can be lowered because the total number of traps in region 415 can be kept small. The doping and composition of layer 407 should be chosen such that the electrical field at surface 413 is not sufficient to cause breakdown at this surface.

On top of layers 407 and mesas 409A and 409B is deposited resistive layer 411 with a thickness of 431. The materials and thickness 431 of layer 411 are chosen such that layer 411 can be fabricated into the passive quench resistor. On top of layer 411 is deposited a top contact layer 420, used to provide contact to the top side of the resistive layer 411. The net result is a two terminal device with contacts 420 and 413, providing contact to a parallel array of series connected SPADs integrated with their passive quench resistors. Note that in the preferred embodiment, layers 411 and 420 are transparent; but they can be opaque in if not in the optical path.

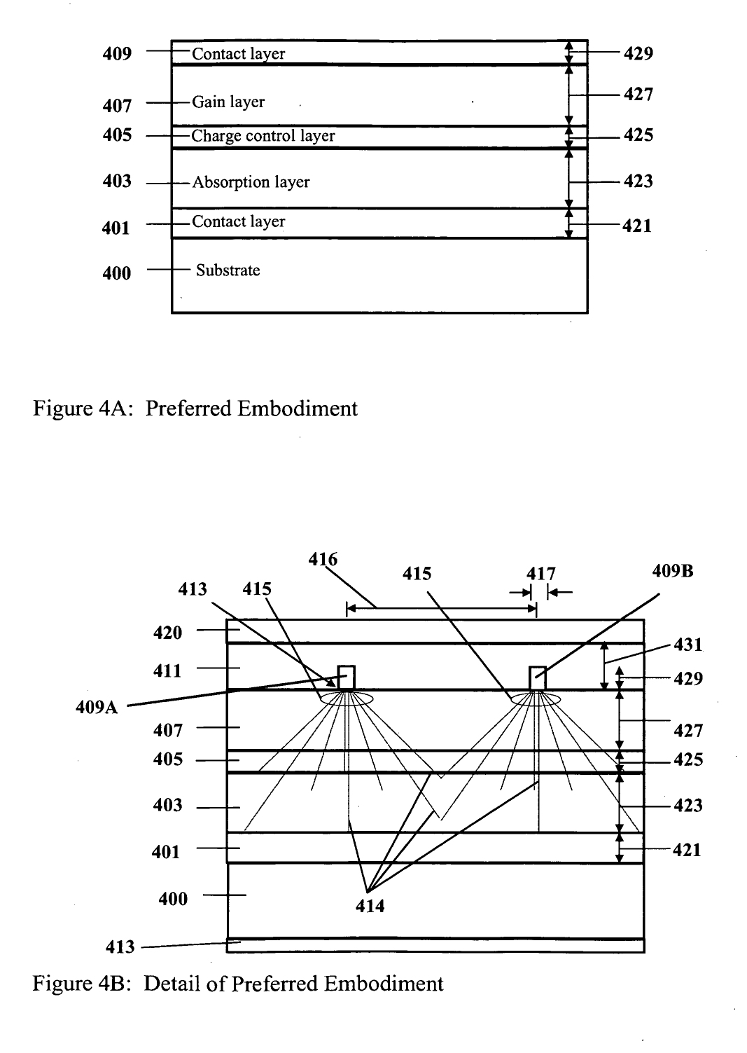

Reference is now made to FIG. 5A, showing an alternative embodiment of the invention. Instead of patterning mesas into layer 409 (as shown in FIG. 4B), layer 409 is doped low enough to be fully depleted when operating under SPAD biasing conditions. The doping of layer 409 also needs to be high enough to prevent breakdown at surface 413B. On top of layer 409 is deposited transparent resistive layer 411, with the resistivity of the layer and thickness 431 chosen to provide the appropriate passive quench resistance. On top of layer 411 is deposited a transparent dielectric layer 419 of thickness 439. This transparent dielectric layer is then patterned and etch to achieve the profile shown, with via hole diameter of 417A and spacing 416A. On top of patterned layer 419 is deposited transparent metal layer 420 used to provide contact to the top side of resistive layer 411. Region 440 defines the individual SPAD contact, while region 441 can be used to provide a field effect guard ring to achieve the desired electrical field profile.

Reference is now made to FIG. 5B, showing another alternative embodiment. The structure in FIG. 5B is similar to that of FIG. 5A, with the primary exception being that layer 411 has been moved from the top of contact layer 409 to on top of patterned layer 413. This alternative embodiment may advantageously simplify processing and provide improved control of the electrical field profile 414 in the device.

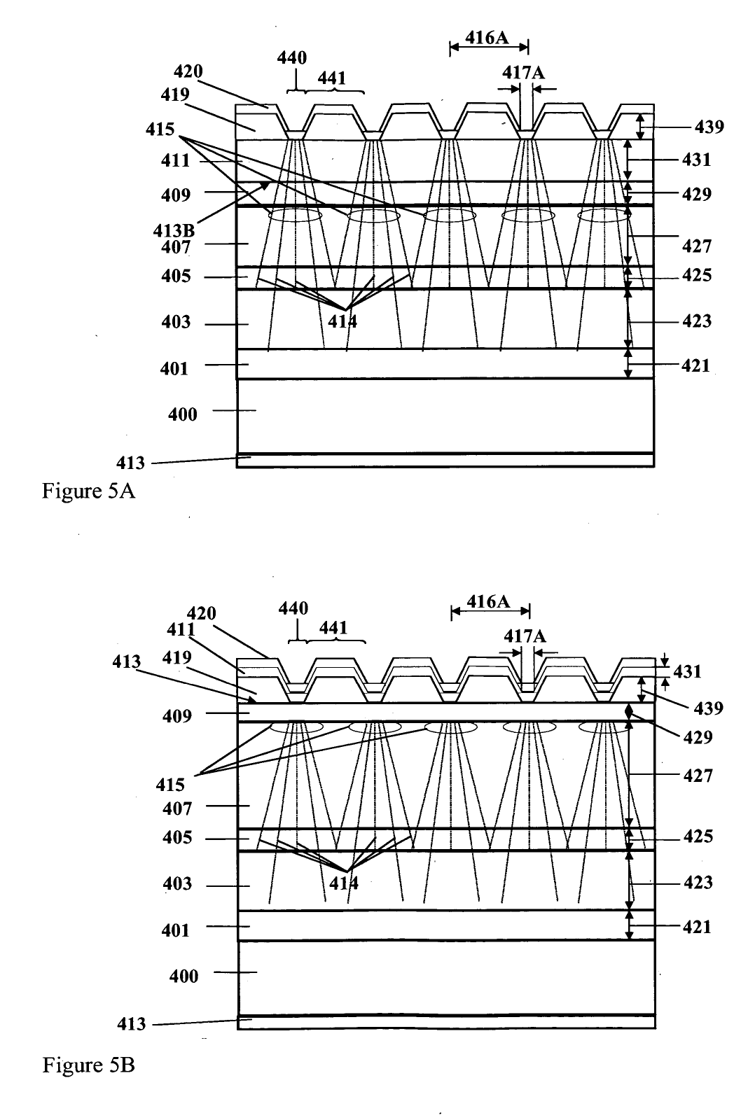

Reference is now made to FIG. 6, showing an alternative embodiment layer structure where resistive layer 411 has been replaced with buried resistive layer 411Y, which can be achieved by epitaxially growing resistive layer 411Y to a thickness 431Y between layers 401 and 403. The composition of layer 411Y and thickness 431Y are chosen to provide the appropriate passive quench resistor values. Devices in accordance with the invention may now be fabricated in accordance with FIGS. 4B, 5A, and 5B but with the resistor layer 411 eliminated (i.e. set thickness 431 to zero).

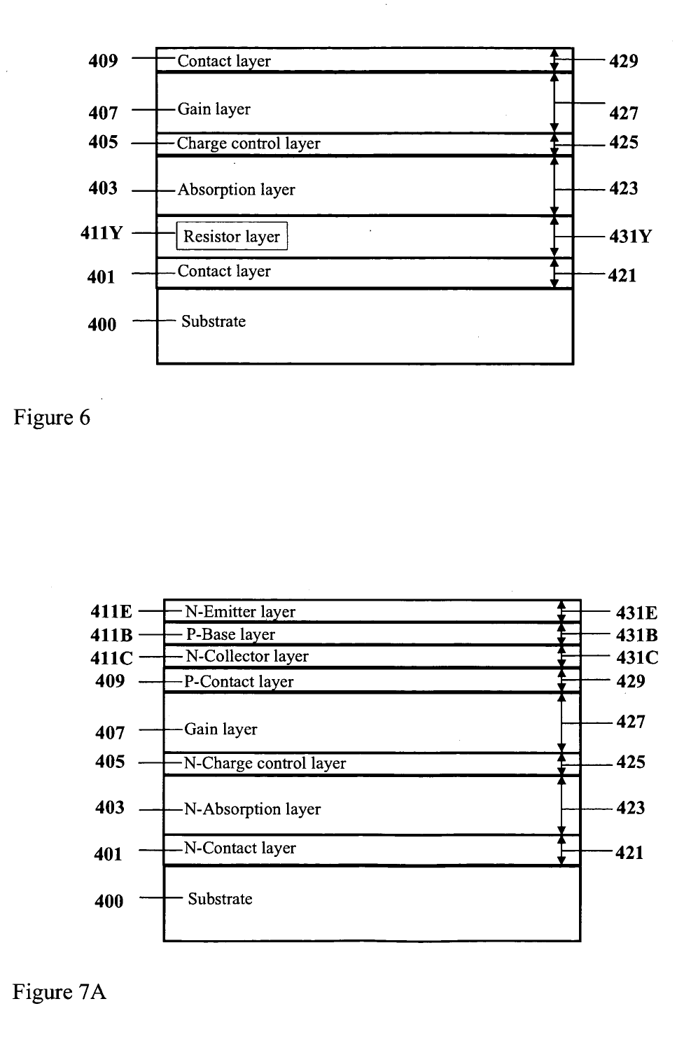

Reference is now made to FIG. 7, showing an alternative embodiment with the current-limiting resistive means needed by the passive quench embodied by using an active resistor such as a bipolar transistor. The layer structure for this alternative embodiment is shown in FIG. 7A, where layer 400 is the substrate, layer 401 of thickness 421 is an n-type anode contact layer, layer 403 of thickness 423 is a n-type absorption region, layer 405 of thickness 425 is a n-type charge control layer, layer 407 of thickness 427 is a lightly doped gain and layer 409 of thickness 429 is a p-type cathode contact layer. These layers are identical to the layers of the preferred embodiment of FIG. 4A. On top of layer 409 is grown a n-type collector layer 411C of thickness 431C, on top of which is grown a p-type base layer 411B of thickness 431B, on top of which is grown a n-type emitter layer 411E of thickness 431E. Ohmic contact between layers 409 and 411C is achieved through the use well known tunnel junction technology.

The equivalent circuit model of this layer structure is shown in FIG. 7B. The transistor 495 consists of emitter layer 411E, base layer 411B, and collector layer 411C. Emitter layer 411E is connected to the bias voltage at 495. Base layer 411B is connected to a second bias supply 494. The bias across the base emitter junction is set by the difference in bias voltages between points 494 and 495, and is used to limit the collector current and thereby provide the current limiting function of the passive quench circuitry. Tunnel diode 496 is formed at the junction of layers 411C and 409, and provides ohmic contact between the collector of 495 and the cathode 492 of SPAD 497. Layer 401 is an ohmic contact to the anode 491 of SPAD 497. The anode 491 can be connected to a transimpedance amplifier 498. Transimpedance amplifier 498 provides a low effective resistance to ground 474, and provides low noise amplification of the Geiger current at connection 473.

Reference is now made to FIG. 7C, showing the common emitter characteristics of transistor 495. The collector current 442 is plotted as a function of collector to emitter bias voltage 441. Curves 443A, 443B, 443C, and 443D are obtained at different base currents. Since the base current is uniquely determined by the bias between points 494 and 495, the transistor acts as an effective current limiter, providing a high effective impedance to the circuit. For example, if the base were biased to achieve the characteristics of curve 443C, then SPAD 497 would be limited to a maximum current 445B under normal operating conditions. Before quenching, the SPAD 497 current is low, forcing the transistor to operating point 445A. Once a Geiger event is initiated, the SPAD 497 current increases, traveling along curve 443C until the device is quenched at point 445B. The slope of curve 443C is its effective collector resistance, and therefore the transistor acts as a relatively low value resistor prior to a detection event at point 445A, and as a high value resistor during a quench cycle at point 445B.

Reference is now made to FIG. 7D showing how the layer structure of FIG. 7A may be fabricated into the circuit elements shown in FIG. 7B for two elements of a SPAD array in accordance with the invention. Mesa isolation is used to isolate adjacent transistor elements as shown in the figure. Isolating adjacent transistor elements also acts to isolate adjacent SPAD pixels 461A and 461B because gain layer 407 is lightly doped and fully depleted under normal SPAD operating conditions. Ohmic contacts 400A and 400B provide low resistance ohmic contact to the common anode layer 401. The emitter contact to the transistor connected to pixel 461A is 457A. The emitter contact to the transistor connected to pixel 461B is 457B. The base contact to the transistor connected to pixel 461A is 458A. The base contact to the transistor connected to pixel 461B is 458B.

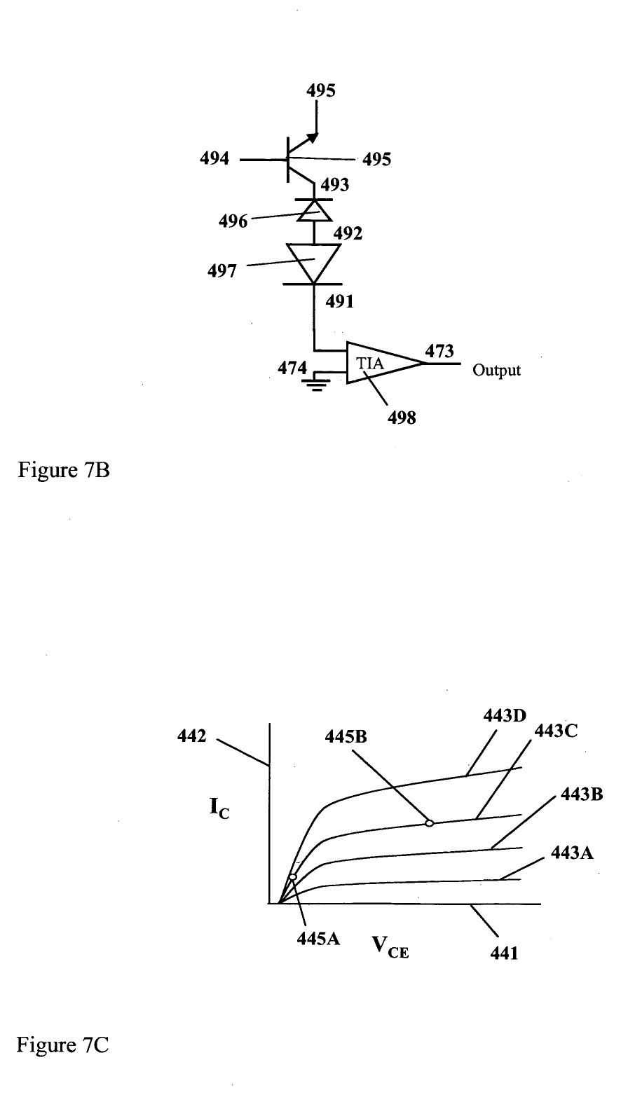

Reference is now made to FIG. 8, showing an alternative embodiment using mesa trench isolation 471 between pixels. Mesa trench isolation is useful if further reductions in optical cross talk is necessary, which can be achieved by inserting an opaque material into trench 471. As shown in the Figure, transparent resistive layer 411 is deposited on top of the layer structure of the preferred embodiment. Transparent conducting contacts 206A and 206B make ohmic contact to one side of resistive layer 411, and contacts 206A and 206B are electrically connected together at bias supply 206Z. With mesa isolation pixels such as those shown in FIG. 8, mesa side wall 470 passivation is important, because it is advantageous to prevent avalanche breakdown at mesa side wall 470, and to keep perimeter leakage current generated at mesa side wall 470 low.

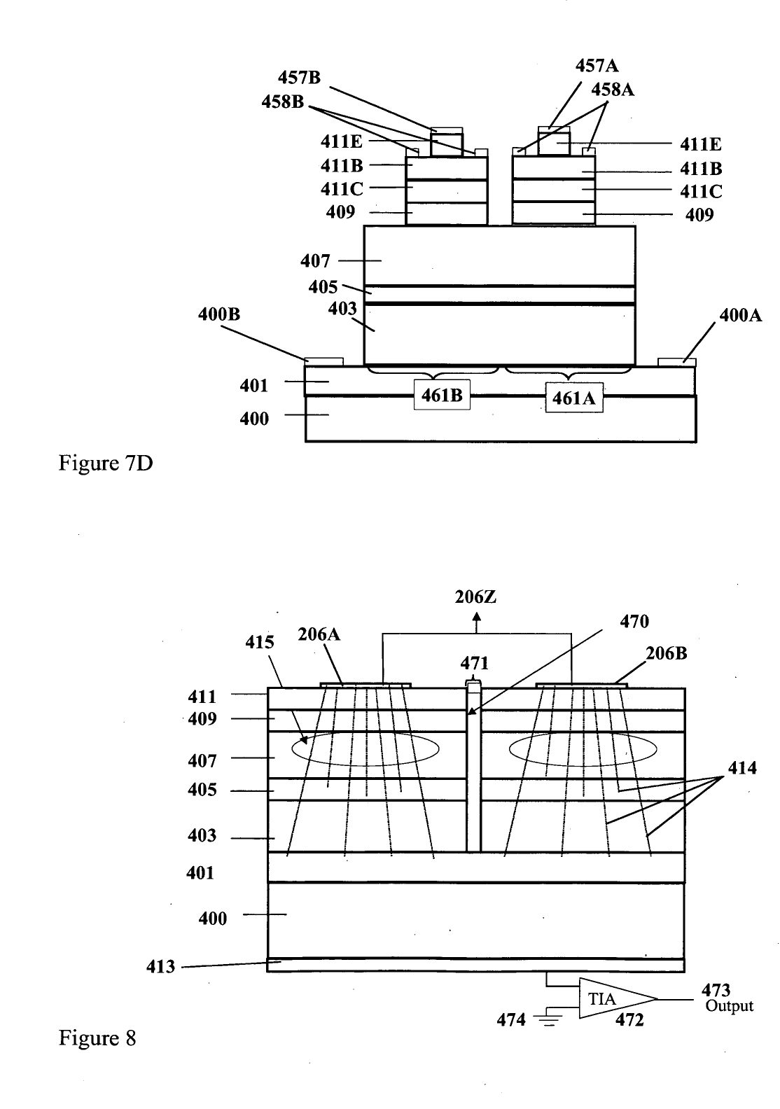

Reference is now made to FIG. 9, showing another alternative embodiment using curved contacts to shape the internal electrical field 414. Curved contacts 480A and 480B are formed by diffusing dopants into those regions using unremarkable doping techniques. After formation of curved contact regions 480A and 480B, resistive layer 411 is deposited, and mesa isolated resistors 411A and 411B are formed to achieve the desired passive quench resistor value. Contacts 206A and 206B make ohmic contact to resistors 411A and 411B respectively. Contacts 206A and 206B are connected together at bias 206Z.

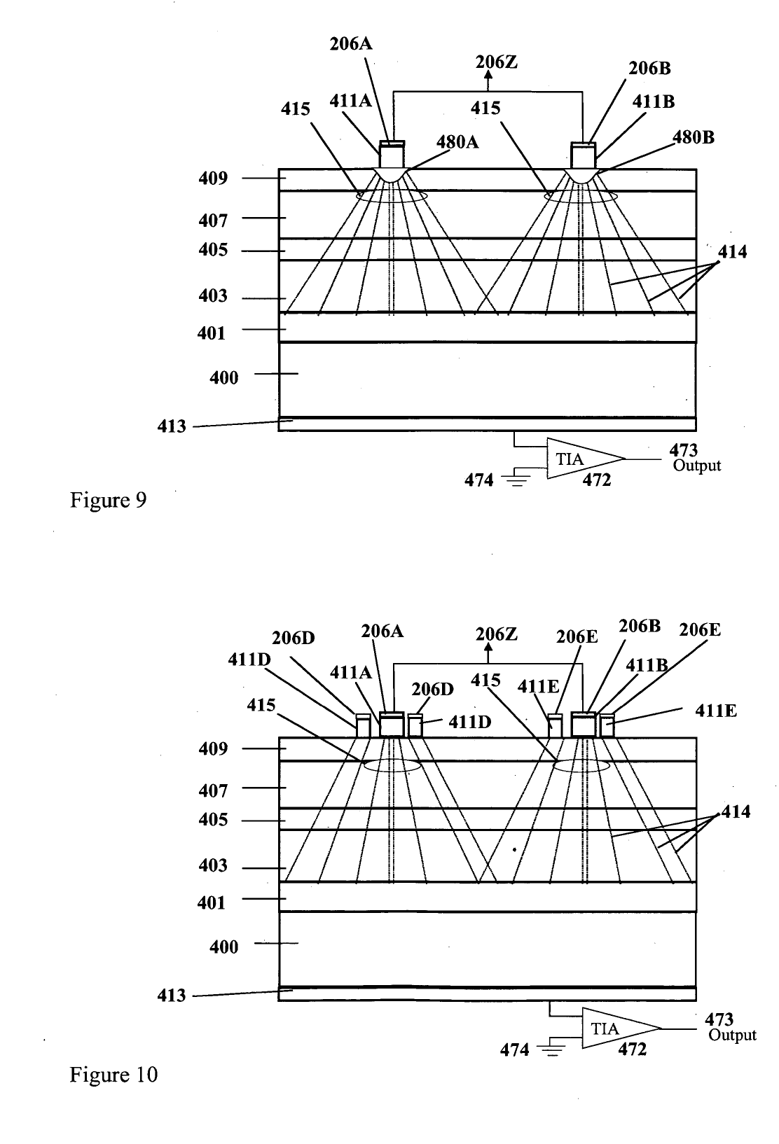

Reference is now made to FIG. 10, showing another alternative embodiment using guard rings 411D and 411E to shape the electrical field 414. Resistor layer 411 is deposited on top of layer 409 to achieve the desired passive quench resistance value. Resistor layer 411 is patterned into mesas 411A and 411B, which provide ohmic contact to the active region of the device, and mesas 411D and 411E, which provide a guard ring function. Contacts 206A and 206B make ohmic contact to mesas 411A and 411B respectively, and are connected to a first voltage supply at 206Z. Contacts 206D and 206E are connected to mesas 411D and 411E respectively, and act as guard rings to shape the electrical field profile 414. Contacts 206D and 206E may be connected to a second voltage supply, chosen such that their voltage is lower than the first voltage supply by an amount chosen to provide optimal guard ring functionality. The guard ring shapes the electrical field profile 414 in order to reduce perimeter effects and enhance the uniformity of the SPAD avalanche gain.

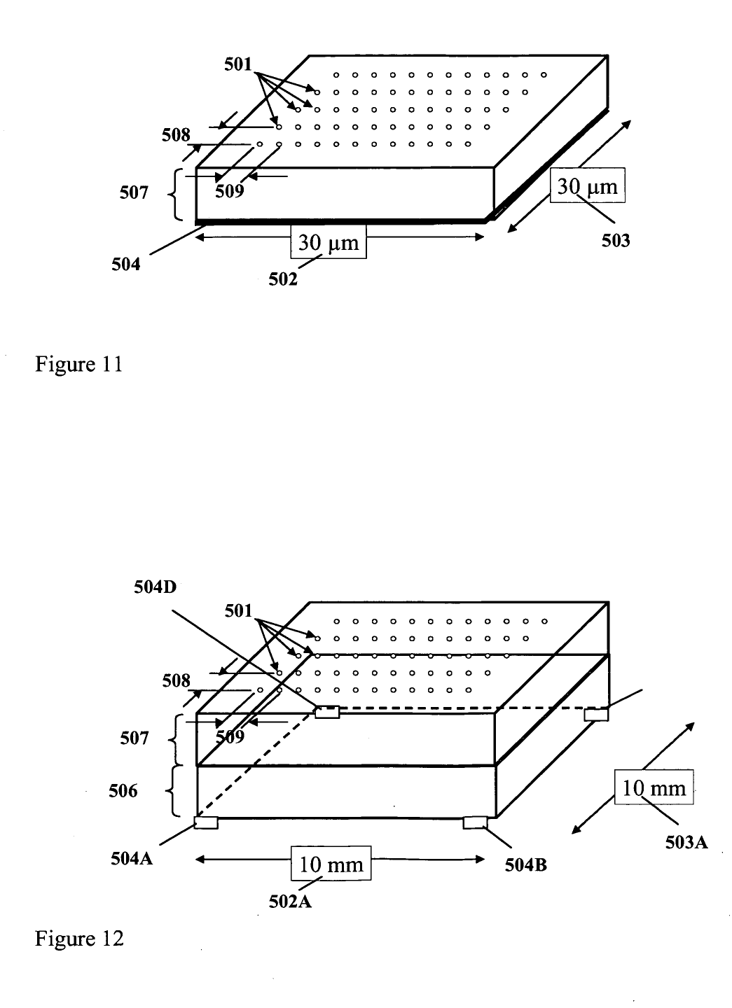

Reference is now made to FIG. 11, showing how SPAD elements can be arranged on a square lattice in accordance with the invention. Elements 501 are individual SPAD photodetector elements, including the integrated passive quench circuitry. The lateral spacing between pixels in a first direction is 509, and the lateral spacing between pixels in a second direction is 508. Dimension 502 is the lateral dimension of the array photodetector in the horizontal direction, and dimension 503 is the lateral dimension of the array photodetector in the vertical direction. Region 507 include the SPAD layers and passive quench circuit elements, with the pixels formed in accordance with the invention. Contact 504 is the common anode connection, which provides a common connection to the anode of all of the pixel elements 501.

Reference is now made to FIG. 12, showing a similar square lattice of pixel elements with total array dimensions 502A and 503A as shown. In addition to region 507 which includes the SPAD layers and passive quench circuit element, an additional resistive layer 506 is connected to the pixels in place of the ohmic contact 504. Resistive layer 506 allows a resistive anode configuration to be used, with the output currents from the pixels being divided between the four corner contacts 504A, 504B, 504C, and 504D. The ratio of the currents through these four corner contacts is related to the distance of the pixel element from the contact, and therefore well known means may be used to determine approximately which pixel element fired based on the ratios of currents through the four contacts. Therefore, such a photodetector may be used as an imaging detector, recording both the time and position of the arrival photons.

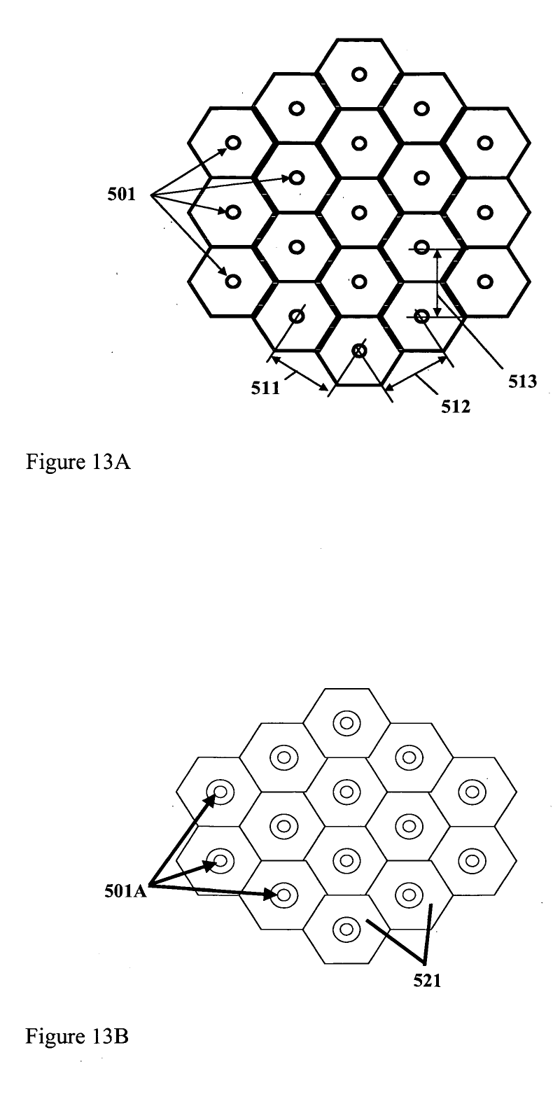

Reference is now made to FIG. 13A, showing an alternative pixel layout on a hexagonal close-packed lattice. Pixel elements 501 are placed on a hexagonal close-packed lattice with length 511, 512, and 513 between pixels as shown. In one embodiment, lengths 511, 512, and 513 are all equivalent. Please note that a hexagonal close-packed shape has the highest fill factor by virtue of using the area most efficiently, but is merely suggestive of area-filling shapes. It is not strictly necessary for the multiplicity of photodetector elements to be spaced regularly, nor necessarily on a repeating grid, nor necessarily with long-range order.

Reference is now made to FIG. 13B, showing an alternative embodiment using a hexagonal close-packed lattice. Contacts 501A make ohmic contact to each pixel element. Contact 521 is a large area guard ring structure used to shape the field around photodetector elements and reduce perimeter effects in accordance with well known principles of guard rings.

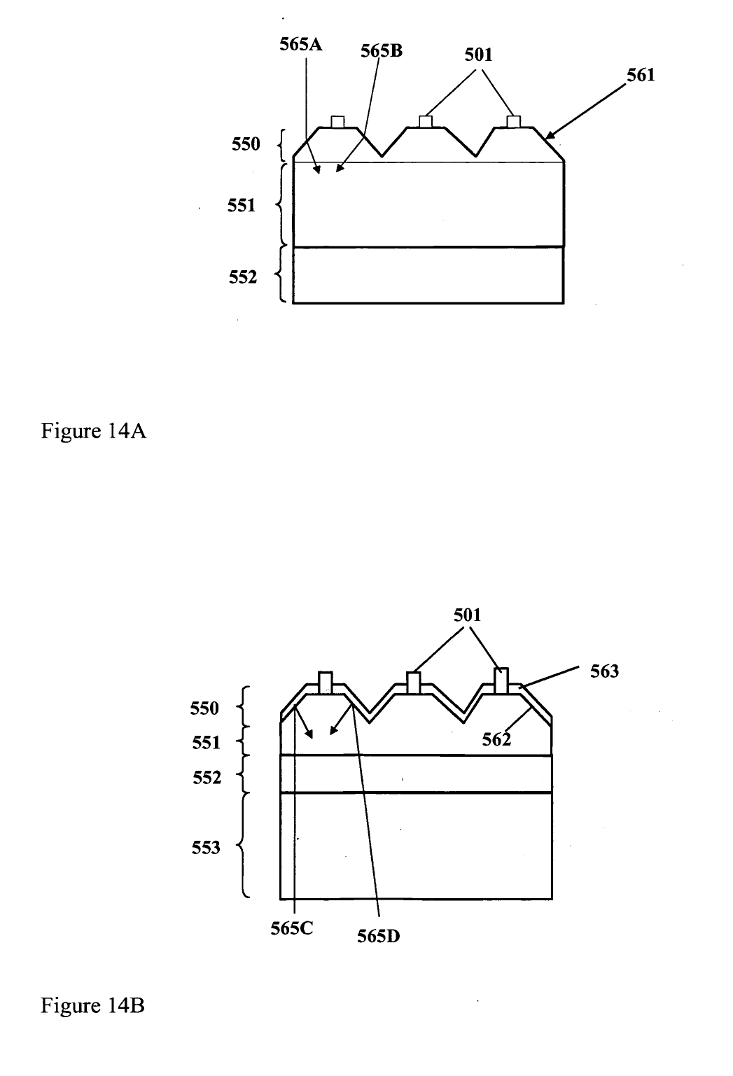

Reference is now made to FIG. 14A, showing an alternative embodiment. Etching of gain layer 550 is used to shape the side wall 561 of the mesa to advantageously refract incident photons 565A and 565B to the active portion of absorption layer 551.

Reference is now made to FIG. 14B, showing an alternative embodiment. Etching of gain layer 550 is used to shape the side wall 562 to advantageously reflect incident photons 565C and 565D into the active region of the device. Photons 565C and 565D are incident from the substrate 553 side of the device, and hence substrate 553 must be substantially transparent to photons 565C and 565D. A dielectric reflective coating 563 is advantageously used to increase the reflection at side wall 562.

Reference is now made to FIG. 14C, showing another alternative embodiment useful for improving the detection efficiency of blue light using the invention. High resistivity layer 561 is inserted between passive quench resistor layer 552 and gain layer 550. Low resistivity regions 562 embedded in layer 561 provide ohmic bottom contacts to gain region 550. Incident photons 563A and 563B are directly incident on absorption layer 551, so avoid exhibit absorption losses. This is particularly important for detecting blue photons because most window layers absorb a significant fraction of the incident blue photons.

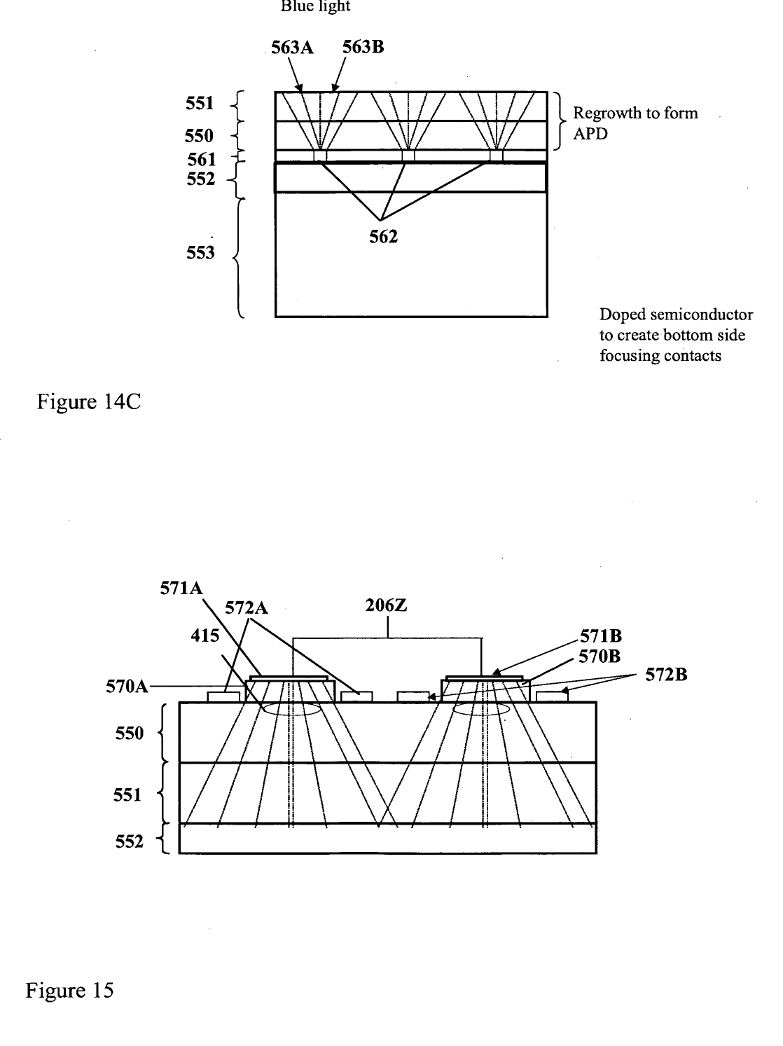

Reference is now made to FIG. 15. In this embodiment, dielectric regions 570A and 570B are used in combination with contacts 571A and 571B to produce a field effect, with the electrical field induced by contacts 571A and 571B penetrating into the active gain region of the device. Contacts 572A and 572B act as both a guard ring and as lateral collection contacts, because dielectric isolation 570A and 570B are unable to collect electrons generated during a Geiger event. This is similar to a field effect transistor, where contacts 571A and 571B would be the gate contacts, and 572A and 572B are equivalent to the drain contacts.

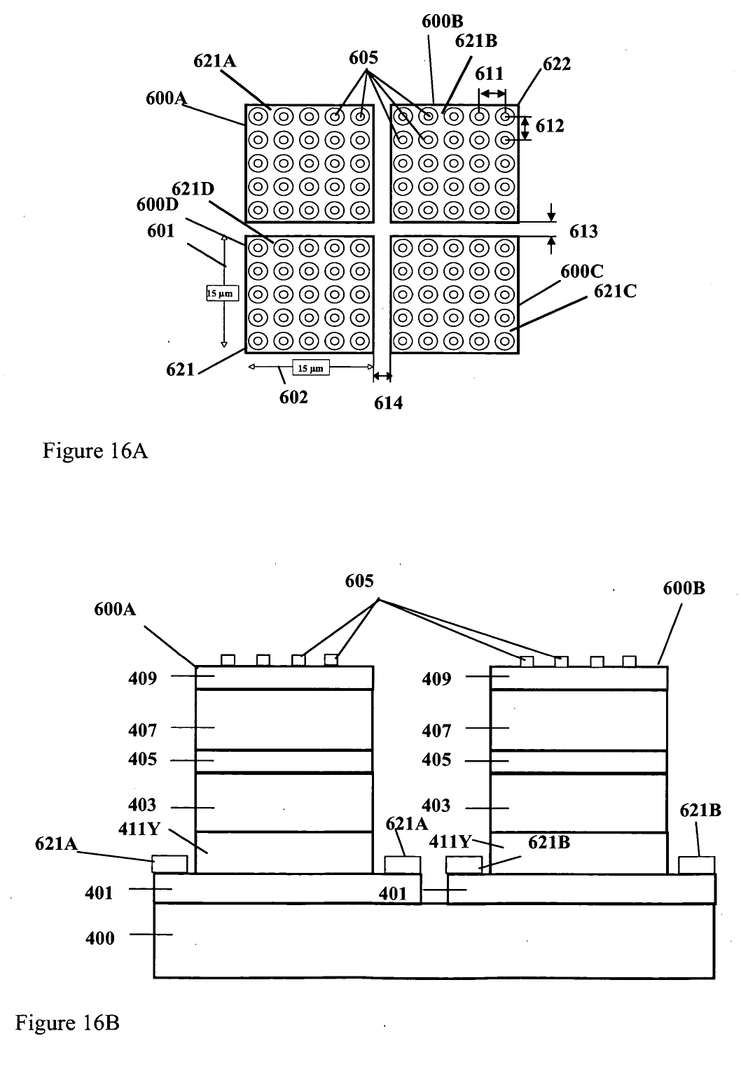

Reference is now made to FIG. 16A showing how an array of common anode connected elements may be used to produce an imaging array. Region 600A is an array of SPADs 605 with a common anode connection 621A in accordance with the invention. Region 600B is an array of SPADs 605 with a common anode connection 621B in accordance with the invention. Region 600C is an array of SPADs 605 with a common anode connection 621C in accordance with the invention. Region 600D is an array of SPADs 605 with a common anode connection 621D in accordance with the invention. The horizontal spacing between SPAD 605 pixel elements is 611 and the vertical spacing between SPAD 605 pixel elements is 612. Each array 600A, 600B, 600C, and 600D has a total horizontal dimension 602 and a total vertical dimension 601. Each array 600A, 600B, 600C, and 600D is separated by horizontal distance 614 and vertical distance 613 to adjacent arrays.

Reference is now made to FIG. 16B showing a cross sectional view of arrays 600A and 600B, including the layer structure of FIG. 6. To maintain high isolation between array 600A and 600B, substrate 400 should be semi-insulating.

The applicants intend to seek, and ultimately receive, claims to all aspects, features and applications of the current invention, both through the present application and through continuing applications, as permitted by 35 U.S.C. §120, etc. Accordingly, no inference should be drawn that applicants have surrendered, or intend to surrender, any potentially patentable subject matter disclosed in this application, but not presently claimed. In this regard, potential infringers should specifically understand that applicants may have one or more additional applications pending, that such additional applications may contain similar, different, narrower or broader claims, and that one or more of such additional applications may be designated as not for publication prior to grant.

We claim:

1. A photodetector comprising a multiplicity of photodetector elements, each of said photodetector elements itself comprising a photodiode designed to operate in Geiger mode with gain always below 10⁶ charge carriers per detected photon.

2. A photodetector in accordance with claim 1 wherein said gain is below 10⁵ charge carriers per detected photon.

3. A photodetector in accordance with claim 1 wherein said gain is below 10⁴ charge carriers per detected photon.

4. A photodetector in accordance with claim 1 wherein said gain is below 10³ charge carriers per detected photon.

5. A photodetector in accordance with claim 1 wherein said gain is produced by an avalanche multiplication process, and said charge carriers are electrons or holes.

6. A photodetector in accordance with claim 5 wherein said detected photon is converted into a plurality of electron-hole pairs in a first region comprised of a first material, and said avalanche multiplication process occurs in a second region formed from a second material including a semiconductor, and said first and second materials are different.

7. A photodetector in accordance with claim 6 wherein said semiconductor is a compound semiconductor.

8. A photodetector in accordance with claim 1 wherein said detected photon is converted into a plurality of electron-hole pairs in a first region including a first semiconductor material, and said avalanche multiplication process occurs in a second region including a second semiconductor material, and the band gap of said first semiconductor material is at least 0.1 eV smaller than the band gap of said second semiconductor material.

9. A photodetector in accordance with claim 1 wherein two or more of said elements connect to the same cathode or anode.

10. A photodetector in accordance with claim 9 including a multiplicity of said anodes or cathodes serving as an array of pixels.

11. A photodetector in accordance with claim 10 wherein said array of pixels forms a line or curve.

12. A photodetector in accordance with claim 10 wherein said array of pixels forms a two-dimensional pixelated photodetector.

13. A photodetector in accordance with claim 1 wherein a multiplicity of said photodetector elements occur in circuits including a resistor in series with said photodetector element.

14. A photodetector in accordance with claim 1 wherein a plurality of said photodetector elements have a capacitance below 1 pF.

15. A photodetector in accordance with claim 14 wherein a plurality of said photodetector elements have a capacitance below 100 fF.

16. A photodetector in accordance with claim 14 wherein a plurality of said photodetector elements have a capacitance below 10 fF.

17. A method for detecting a dim optical signal with gray scale dynamic range comprising the steps of distributing an optical signal over a multiplicity of photodetector elements such that said multiplicity of photodetector elements is illuminated by an approximately common intensity, converting said optical signal into an electrical representation in each of said photodetector elements, and amplifying said electrical representation at or within each photodetector element using Geiger mode gain of less than 10⁶.

18. The method of claim 17 wherein said Geiger mode gain is less than 10³.

19. The method of claim 17 further including the step of limiting the supply current to a photodetector element by means of a resistive means in series such that said Geiger mode gain is sufficient to cause said photodetector element to self-quench.

20. The method of claim 17 further including the step of resetting a photodetector element after it quenches by means of moving a current through said resistive means and said photodetector element in series.

21. The method of claim 17 wherein said optical signal includes a wavelength below 870 nm and a multiplicity of said photodetector elements employ a compound semiconductor.

22. The method of claim 17 further including the step of summing the currents produced thereby at a common cathode or common anode.

23. A method for detecting a dim optical signal with gray scale dynamic range comprising the steps of distributing an optical signal over a multiplicity of single-photon avalanche detectors, and summing the currents produced thereby using a cathode or anode shared in common.

24. The method of claim 23 applied in parallel to an array of independent said multiplicities.
